(19) United States
(12) Patent Application Publication
(10) Pub. No.: US 2025/0006799 A1
(43) Pub. Date: Jan. 2, 2025

(54) SEMICONDUCTOR SUBSTRATE, SEMICONDUCTOR DEVICE, METHOD FOR PRODUCING SEMICONDUCTOR SUBSTRATE, AND METHOD FOR PRODUCING SEMICONDUCTOR DEVICE

(71) Applicants: AIR WATER INC., Chuo-ku, Osaka-shi, Osaka (JP); UNIVERSITY PUBLIC CORPORATION OSAKA, Abeno-ku, Osaka-shi, Osaka (JP)

(72) Inventors: Keisuke KAWAMURA, Matsumoto-shi, Nagano (JP); Koichi KITAHARA, Matsumoto-shi, Nagano (JP); Naoteru SHIGEKAWA, Osaka-shi, Osaka (JP); Jianbo LIANG, Osaka-shi, Osaka (JP)

(21) Appl. No.: 18/694,847

(22) PCT Filed: Sep. 21, 2022
(86) PCT No.: PCT/JP2022/035083

§ 371 Date: Mar. 22, 2024

(30) Foreign Application Priority Data
Sep. 22, 2021 (JP) 2021-154082

(51) Int. Cl. H01L 29/267; H01L 21/02; H01L 23/00; H01L 23/373; H01L 29/04; H01L 29/778; H01L 29/872

(52) U.S. Cl. CPC H01L 29/267; H01L 23/3732; H01L 24/29; H01L 24/32; H01L 24/83; H01L 29/045; H01L 21/02529; H01L 21/0254; H01L 29/7786; H01L 29/872; H01L 2224/29082; H01L 2224/291; H01L 2224/29193; H01L 2224/32225; H01L 2224/83894; H01L 2924/04642

(57) ABSTRACT

A semiconductor substrate, a semiconductor device, a method for manufacturing a semiconductor substrate, and a method for manufacturing a semiconductor device are provided. The semiconductor substrate has a thermal conduction layer, a SiC (silicon carbide) layer formed on one principal surface side of the thermal conduction layer, having a 3C crystal structure, a bonding layer formed between the thermal conduction layer and the SiC layer, and a nitride semiconductor layer formed on one principal surface of the SiC layer.

### BACKGROUND OF THE INVENTION

### Technological Field

The present invention relates to a semiconductor substrate, a semiconductor device, a method for manufacturing a semiconductor substrate, and a method for manufacturing a semiconductor device. More specifically, the present invention relates to a semiconductor substrate and a semiconductor device both equipped with a thermal conduction layer made of diamond or polycrystalline silicon carbide, and methods for manufacturing such a semiconductor substrate and semiconductor device.

### Description of the Related Art

Nitride semiconductors, such as GaN (gallium nitride), have characteristics such as a wide bandgap and high electron saturation velocity. Therefore, nitride semiconductor devices using nitride semiconductor layers are promising devices for high-frequency and power applications. For example, non-patent document 1 below discloses a nitride semiconductor device equipped with an SOI (Silicon On Insulator) substrate and a HEMT (High Electron Mobility Transistor) formed on the Si layer within the SOI substrate.

As disclosed in below non-patent document 1, nitride semiconductor devices are generally formed on substrates with low thermal conductivity, such as SOI substrates, sapphire substrates, or Si (silicon) substrates. Therefore, heat generated by the nitride semiconductor devices during operation is not easily dissipated through the substrates. As a result, the temperature of nitride semiconductor devices can easily rise, potentially decreasing the performance and reliability of the nitride semiconductor devices. Particularly, in the non-patent document 1, the SiO₂ (silicon dioxide) layer within the SOI substrate has a significantly low thermal conductivity, hindering the heat dissipation of the nitride semiconductor devices.

Non-patent document 2 below, as well as patent documents 1 and 2 below, discloses technologies for enhancing the heat dissipation of nitride semiconductor devices using a diamond layer. Since diamond has very high thermal conductivity, it is a promising candidate material for heat spreaders in nitride semiconductor devices. Non-patent document 2 below discloses a nitride semiconductor device that includes a diamond layer, a SiC (silicon carbide) layer formed on the diamond layer through a metal layer made of Ti (titanium), and a HEMT formed on the SiC layer. The structure disclosed in the non-patent document 2 is manufactured by the following method: A nitride semiconductor layer is epitaxially grown on the surface of a SiC substrate containing micropipes. A nitride semiconductor device including the HEMT is manufactured by processing this nitride semiconductor layer. A 50 μm thick SiC layer is produced by cutting the backside of the SiC substrate. The backside of the SiC layer and the diamond layer are bonded through a metal layer made of Ti with a thickness of 10 nm.

Patent document 1 below discloses a semiconductor device comprising a support substrate made of diamond, a monocrystalline SiC layer with a resistivity of 10\hat{\hat{ }}6 to 10\hat{\hat{ }}12 Ω·cm and a thickness of 1 to 30 μm, and a nitride semiconductor layer. In this semiconductor device, one surface of the monocrystalline SiC layer is bonded to the support substrate. The monocrystalline SiC layer contains micropipes. The nitride semiconductor layer is formed on the other surface of the monocrystalline SiC layer. The structure disclosed in patent document 1 below is manufactured by the following method. A monocrystalline SiC substrate is prepared. Hydrogen ions are implanted into the surface of the monocrystalline SiC substrate, forming a hydrogen ion implantation layer within the monocrystalline SiC substrate. The surface of the monocrystalline SiC substrate is bonded to a support substrate made of diamond. Thermal treatment is performed on the support substrate and the monocrystalline SiC substrate, causing the monocrystalline SiC substrate to be separated at the hydrogen ion implantation layer. As a result, the remaining part of the monocrystalline SiC substrate becomes a monocrystalline SiC layer. The hydrogen ion implantation layer remaining on the backside of the monocrystalline SiC layer is removed by CMP (Chemical Mechanical Polishing). A nitride semiconductor layer is formed on the backside of the monocrystalline SiC layer by epitaxial growth.

Patent document 2 below discloses the following method for manufacturing a nitride semiconductor substrate. A diamond layer is formed on an Si substrate. The Si substrate is thinned, and the remaining Si portion is carbonized, forming a monocrystalline SiC layer. A nitride semiconductor layer is formed on the surface of the monocrystalline SiC layer that does not have the diamond layer formed on it.

### PRIOR ART DOCUMENTS

[Patent Document 1] Japanese Laid-Open Patent Publication No. 2016-139655
[Patent Document 2] Japanese Laid-Open Patent Publication No. 2018-203587 (U.S. Pat. No. 6,763,347)
[Non-Patent Document 1] Xiangdong Li, et al., “Suppression of the Backgating Effect of Enhancement-Mode p-GaN HEMTs on 200-mm GaN-on-SOI for Monolithic Integration,” IEEE Electron Device Lett., 39, 999 (2018).
[Non-Patent Document 2] Yuichi Minoura, et al., “Surface activated bonding of SiC/diamond for thermal management of high-output power GaN HEMTs,” Jpn. J. Appl. Phys., 59, SGGD03 (2020).

However, the conventional technology that uses a thermal conduction layer made of diamond or similar materials to enhance the heat dissipation of semiconductor devices had a problem of low quality in the nitride semiconductor layer.

Specifically, the technologies in non-patent document 2 and patent document 1 use a bulk SiC substrate as the SiC layer. Generally, a bulk SiC substrate has a 4H crystal structure and contains micropipes. Therefore, the quality of the nitride semiconductor layer formed on the SiC layer was deteriorated due to the influence of micropipes contained in the SiC layer.

Also, in the technology of patent document 1, the surface that serves as the base for epitaxial growth of the nitride semiconductor layer is obtained by implanting hydrogen ions into the SiC substrate, then heating the substrate to fracture the SiC layer at the ion implantation layer, and the fractured surface is CMP processed. Since SiC is a material with high Mohs hardness, the fractured surface has significant roughness, and crystal defects are likely to occur from the rough and uneven parts. Thus, because the fractured surface with significant roughness and defects is subjected to CMP processing, the uniformity within the surface of the CMP-processed face is low. Therefore, the quality of the nitride semiconductor layer formed on the SiC layer was deteriorated due to the low uniformity within the CMP-processed surface. Furthermore, in the technology of patent document 1, the nitride semiconductor layer is formed after bonding the monocrystalline SiC layer and the support substrate. Since the monocrystalline SiC layer is heated to a high temperature when forming the nitride semiconductor layer, the bond between the monocrystalline SiC layer and the support substrate weakens, significantly reducing the reliability of the semiconductor device.

In the technology of patent document 2, the monocrystalline SiC layer is formed by carbonizing the Si substrate. It is difficult to obtain a thick and high-quality SiC layer by carbonizing the Si substrate. Therefore, it was not possible to form a SiC layer with sufficient thickness and crystallinity for the epitaxial growth of the nitride semiconductor layer, and the quality of the grown nitride semiconductor layer was deteriorated.

### SUMMARY OF THE INVENTION

This invention aims to solve the above issues, providing a semiconductor substrate, a semiconductor device, a method for manufacturing a semiconductor substrate, and a method for manufacturing a semiconductor device that can improve the quality of the nitride semiconductor layer.

Another objective of this invention is to provide a semiconductor substrate, a semiconductor device, a method for manufacturing a semiconductor substrate, and a method for manufacturing a semiconductor device that can improve the performance of the device.

A semiconductor substrate according to one aspect of this invention comprises a thermal conduction layer made of diamond or polycrystalline silicon carbide, a silicon carbide layer formed on one principal side of the thermal conduction layer having a 3C crystal structure, a bonding layer formed between the thermal conduction layer and the silicon carbide layer, and a nitride semiconductor layer formed on one principal side of the silicon carbide layer.

Preferably, in the semiconductor substrate, the silicon carbide layer and the nitride semiconductor layer are in contact with each other, and there is no amorphous layer between the silicon carbide layer and the nitride semiconductor layer.

Preferably, in the semiconductor substrate, the thermal conduction layer is made of diamond, and the bonding layer includes a first amorphous layer formed on one principal surface of the thermal conduction layer, primarily consisting of carbon, and a second amorphous layer formed between the first amorphous layer and the silicon carbide layer, primarily consisting of carbon and silicon.

Preferably, in the semiconductor substrate, the silicon carbide layer is monocrystalline, the thermal conduction layer is made of diamond, and the bonding layer includes, at least, polycrystalline grains of silicon carbide.

Preferably, in the semiconductor substrate, the thermal conduction layer is made of diamond, and the bonding layer includes a region where the density of carbon atoms decreases, with the carbon atom density decreasing monotonically from the thermal conduction layer towards the silicon carbide layer, and the thickness of the region where the carbon atom density decreases is 2 nm or more.

Preferably, in the semiconductor substrate, the bonding layer includes silicon dioxide.

Preferably, in the semiconductor substrate, the silicon carbide layer does not contain micropipes.

Preferably, in the semiconductor substrate, the silicon carbide layer has a thickness of 0.1 μm or more and 5 μm or less.

Preferably, in the semiconductor substrate, one principal side of the silicon carbide layer has a surface orientation of (1, 1, 1), (−1, −1, −1), or (1, 0, 0).

Preferably, in the semiconductor substrate, the thermal conduction layer is made of diamond and has a resistivity of 5×10\hat{ }3 Ω·cm or more and 1×10\hat{ }16 Ω·cm or less.

Preferably, in the semiconductor substrate, the silicon carbide layer has an electron concentration of 1×10\hat{ }15 cm\hat{ }−3 or more and 1×10\hat{ }21 cm\hat{ }−3 or less.

Preferably, in the semiconductor substrate, the nitride semiconductor layer includes a first nitride semiconductor layer formed on one principal surface side of the silicon carbide layer, includes an insulating or semi-insulating layer, and is made of AlₓGa₁₋ₓN (0.1≤x≤1), and a second nitride semiconductor layer formed on one principal surface side of the first nitride semiconductor layer, includes a main layer made of insulating or semi-insulating Al_{y}Ga_{1-y}N (0≤y≤0.1), and an electron transit layer formed on one principal surface side of the second nitride semiconductor layer, made of Al_{z}Ga_{1-z}N (0≤z≤0.1), and a barrier layer formed on one principal surface side of the electron transit layer, having a wider bandgap than the electron transit layer, with the nitride semiconductor layer having a thickness of 6 μm or more and 10 μm or less.

Preferably, in the semiconductor substrate, the thermal conduction layer is made of diamond, the nitride semiconductor layer has a thickness of 0.5 μm or more and less than 6 μm, the thermal conduction layer has a resistivity of 5×10\hat{ }3 Ω·cm or more and 1×10\hat{ }16 Ω·cm or less, and the silicon carbide layer has a resistivity of 1×10\hat{ }3 Ω·cm or more and 1×10\hat{ }16 Ω·cm or less.

A semiconductor device according to another aspect of this invention includes the above semiconductor substrate, and first and second electrodes formed on one principal surface side of the silicon carbide layer, with the first electrode being electrically connected to the silicon carbide layer.

Preferably, in the semiconductor device, the nitride semiconductor layer includes a via hole reaching from one principal surface side of the nitride semiconductor layer to the silicon carbide layer, the first electrode is formed on one principal surface side of the nitride semiconductor layer, and the device further comprises an electrically conductive layer that electrically connects the first electrode and the silicon carbide layer formed inside the via hole.

Preferably, in the semiconductor device, each of the silicon carbide layer, the nitride semiconductor layer, and the first and second electrodes are plural, each of the plural silicon carbide layers is formed on one principal surface side of the thermal conduction layer and is insulated from each other, each of the plural nitride semiconductor layers is formed on one principal surface side of each of the plural silicon carbide layers, and each of the plural first and second electrodes is formed on one principal surface side of each of the plural silicon carbide layers.

A semiconductor device according to another aspect of this invention includes the above semiconductor substrate, a source electrode and a gate electrode formed on one principal surface side of the nitride semiconductor layer, and a drain electrode formed on one principal surface side of the silicon carbide layer.

A method for manufacturing a semiconductor substrate according to another aspect of this invention comprises the steps of forming a silicon carbide layer having a 3C crystal structure on one principal surface of a silicon substrate, forming a nitride semiconductor layer on one principal surface of the silicon carbide layer, removing the silicon substrate from the silicon carbide layer, and bonding another principal surface of the silicon carbide layer with one principal surface of a thermal conduction layer made of diamond or polycrystalline silicon carbide.

Preferably, in the manufacturing method, the step of forming the silicon carbide layer includes the steps of forming a first silicon carbide layer by carbonizing one principal surface of the silicon substrate, and forming a second silicon carbide layer by crystalline growth of silicon carbide on one principal surface of the first silicon carbide layer.

A method for manufacturing a semiconductor device according to another aspect of this invention comprises the steps of manufacturing a semiconductor substrate by the above method for manufacturing a semiconductor substrate, forming first and second electrodes on one principal surface side of the silicon carbide layer, and electrically connecting the first electrode with the silicon carbide layer.

A method for manufacturing a semiconductor device according to another aspect of this invention comprises the steps of forming a silicon carbide layer having a 3C crystal structure on one principal surface of a silicon substrate, manufacturing a semiconductor substrate by forming a nitride semiconductor layer on one principal surface of the silicon carbide layer, manufacturing a device on the semiconductor substrate, exposing another principal surface of the silicon carbide layer by removing the silicon substrate after manufacturing the device, and bonding another principal surface of the silicon carbide layer with one principal surface of a thermal conduction layer made of diamond or polycrystalline silicon carbide after exposing another principal surface of the silicon carbide layer.

According to the present invention, it is possible to provide a semiconductor substrate, a semiconductor device, a method for manufacturing a semiconductor substrate, and a method for manufacturing a semiconductor device that can improve the quality of the nitride semiconductor layer. Furthermore, it is possible to provide a semiconductor substrate, a semiconductor device, a method for manufacturing a semiconductor substrate, and a method for manufacturing a semiconductor device that can enhance the performance of the device.

### BRIEF DESCRIPTION OF THE DRAWINGS

FIG. 1 A cross-sectional view showing the structure of semiconductor substrate NS1 in the first embodiment of the present invention.

FIG. 2 A cross-sectional view showing the first step in the manufacturing method of semiconductor substrate NS1 in the first embodiment of the present invention.

FIG. 3 A cross-sectional view showing the second step in the manufacturing method of semiconductor substrate NS1 in the first embodiment of the present invention.

FIG. 4 A cross-sectional view showing the third step in the manufacturing method of semiconductor substrate NS1 in the first embodiment of the present invention, using surface activation bonding.

FIG. 5 A cross-sectional view showing the fourth step in the manufacturing method of semiconductor substrate NS1 in the first embodiment of the present invention, using surface activation bonding.

FIG. 6 An enlarged view of the key part in FIG. 5.

FIG. 7 A partial cross-sectional view showing the structure of the bonding part 3 when heat treatment is applied to the bonding layer 3 after bonding using surface activation bonding in the first embodiment of the present invention.

FIG. 8 The first diagram showing the carbon atom density along the thickness direction in the bonding layer 3.

FIG. 9 The second diagram showing the carbon atom density along the thickness direction in the bonding layer 3.

FIG. 10 A cross-sectional view showing the third step in the manufacturing method of semiconductor substrate NS1 in the first embodiment of the present invention, using hydrophilic bonding.

FIG. 11 A cross-sectional view showing the fourth step in the manufacturing method of semiconductor substrate NS1 in the first embodiment of the present invention, using hydrophilic bonding.

FIG. 12 An enlarged view of the key part in FIG. 11.

FIG. 13 A comparison diagram of the band lineup between 3C—SiC/GaN and 4H—SiC/GaN.

FIG. 14 A cross-sectional view showing the first step in the first variation of the manufacturing method of semiconductor substrate NS1 in the first embodiment of the present invention.

FIG. 15 A cross-sectional view showing the second step in the first variation of the manufacturing method of semiconductor substrate NS1 in the first embodiment of the present invention, using surface activation bonding.

FIG. 16 A cross-sectional view showing the third step in the first variation of the manufacturing method of semiconductor substrate NS1 in the first embodiment of the present invention, using surface activation bonding.

FIG. 17 A cross-sectional view showing the fourth step in the first variation of the manufacturing method of semiconductor substrate NS1 in the first embodiment of the present invention.

FIG. 18 A cross-sectional view showing the first step in the second variation of the manufacturing method of semiconductor substrate NS1 in the first embodiment of the present invention.

FIG. 19 A cross-sectional view showing the second step in the second variation of the manufacturing method of semiconductor substrate NS1 in the first embodiment of the present invention, using surface activation bonding.

FIG. 20 A cross-sectional view showing the third step in the second variation of the manufacturing method of semiconductor substrate NS1 in the first embodiment of the present invention, using surface activation bonding.

FIG. 21 A cross-sectional view showing the fourth step in the second variation of the manufacturing method of semiconductor substrate NS1 in the first embodiment of the present invention.

FIG. 22 A cross-sectional view showing the structure of semiconductor device ND1 in the second embodiment of the present invention.

FIG. 23 A cross-sectional view showing the first step in the manufacturing method of semiconductor device ND1 in the second embodiment of the present invention.

FIG. 24 A cross-sectional view showing the second step in the manufacturing method of semiconductor device ND1 in the second embodiment of the present invention.

FIG. 25 A cross-sectional view showing the third step in the manufacturing method of semiconductor device ND1 in the second embodiment of the present invention.

FIG. 26 A cross-sectional view showing the fourth step in the manufacturing method of semiconductor device ND1 in the second embodiment of the present invention.

FIG. 27 A cross-sectional view showing the fifth step in the manufacturing method of semiconductor device ND1 in the second embodiment of the present invention.

FIG. 28 A cross-sectional view showing the sixth step in the manufacturing method of semiconductor device ND1 in the second embodiment of the present invention.

FIG. 29 A cross-sectional view showing the seventh step in the manufacturing method of semiconductor device ND1 in the second embodiment of the present invention.

FIG. 30 A cross-sectional view showing the structure of semiconductor device ND2 in the third embodiment of the present invention.

FIG. 31 A cross-sectional view showing the first step in the manufacturing method of semiconductor device ND2 in the third embodiment of the present invention.

FIG. 32 A cross-sectional view showing the second step in the manufacturing method of semiconductor device ND2 in the third embodiment of the present invention.

FIG. 33 A cross-sectional view showing the structure of semiconductor device ND3 in the fourth embodiment of the present invention.

FIG. 34 A diagram showing the distribution of Al composition ratio inside the first nitride semiconductor layer 410 in the fourth embodiment of the present invention.

FIG. 35 A schematic diagram showing the two-dimensional growth of GaN constituting the C—GaN layer 421.

FIG. 36 A plan view showing the structure of semiconductor substrate NS2 in the fourth embodiment of the present invention.

FIG. 37 A cross-sectional view showing the first step in the variation of the manufacturing method of semiconductor device ND3 in the fourth embodiment of the present invention.

FIG. 38 A cross-sectional view showing the second step in the variation of the manufacturing method of semiconductor device ND3 in the fourth embodiment of the present invention.

FIG. 39 A cross-sectional view showing the third step in the variation of the manufacturing method of semiconductor device ND3 in the fourth embodiment of the present invention.

FIG. 40 A cross-sectional view showing the fourth step in the variation of the manufacturing method of semiconductor device ND3 in the fourth embodiment of the present invention.

FIG. 41 A cross-sectional view showing the fifth step in the variation of the manufacturing method of semiconductor device ND3 in the fourth embodiment of the present invention.

FIG. 42 A diagram showing structures ST1 and ST2 in the first example of the present invention.

FIG. 43 A diagram showing the relationship between the gate-drain distance LDG and the breakdown voltage for samples 1-5 in the first example of the present invention.

FIG. 44 A diagram showing structures ST3 and ST4 in the second example of the present invention.

FIG. 45 A graph showing the total thermal resistance for samples 6-8 in the second example of the present invention.

FIG. 46 A table showing the thermal resistance of each layer and the total thermal resistance for multiple layers constituting samples 6-8 in the second example of the present invention.

FIG. 47 A diagram showing the relationship between the thermal resistance and the thickness D of the nitride semiconductor layer 1013 for samples 6 and 8 in the second example of the present invention.

FIG. 48 A TEM image of the cross-section of the bonding layer for sample 9 in the third example of the present invention.

FIG. 49 A TEM image of the cross-section of the bonding layer for sample 10 in the third example of the present invention.

FIG. 50 A TEM image of the cross-section of the bonding layer for sample 11 in the third example of the present invention.

FIG. 51 A diagram showing the distribution of atomic density along the depth from the surface of the SiC layer for samples 9-11 in the third example of the present invention.

### DETAILED DESCRIPTION OF EMBODIMENTS

Below, embodiments of the present invention are explained based on the drawings. In the following description, the expression “formed on the principal surface” means that it is formed in contact with that principal surface. The expression “formed on the side of the principal surface” means both that it is formed in contact with that principal surface and that it is formed without contacting (spaced apart from) that principal surface.

### First Embodiment

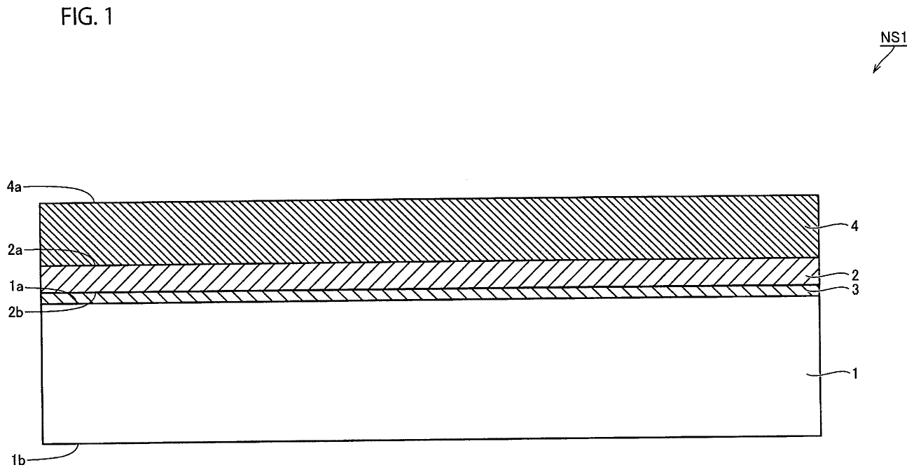

FIG. 1 is a cross-sectional view showing the structure of semiconductor substrate NS1 in the first embodiment of the present invention. In the drawings, the bonding layer 3 is depicted thicker than its actual thickness.

Referring to FIG. 1, the semiconductor substrate NS1 (an example of a semiconductor substrate) in the first embodiment is a substrate for manufacturing semiconductor devices, comprising a diamond substrate 1 (an example of a thermal conduction layer), an SiC layer 2 (an example of a silicon carbide layer), a bonding layer 3 (an example of a bonding layer), and a nitride semiconductor layer 4 (an example of a nitride semiconductor layer). The diamond substrate 1 is a thermal conduction layer made of diamond. The diamond substrate 1 is, for example, polycrystalline. The diamond substrate 1 has a thickness of, for example, 100 μm to 6000 μm. The diamond substrate 1 has principal surfaces 1a and 1b. The principal surface 1a of the diamond substrate 1 faces upwards in FIG. 1. The principal surface 1b of the diamond substrate 1 faces downwards in FIG. 1.

The SiC layer 2 is formed on the side of the principal surface 1a of the diamond substrate 1. The SiC layer 2 is bonded to the diamond substrate 1. The SiC layer 2 is monocrystalline and has a 3C crystal structure. The SiC layer 2 includes two principal surfaces 2a and 2b. The principal surface 2a of the SiC layer 2 faces upwards in FIG. 1, and the principal surface 2b of the SiC layer 2 faces downwards in FIG. 1. The principal surface 2a of the SiC layer 2 has a surface orientation of, for example, (111), (−1−1−1), or (100), preferably (111) or (−1−1−1).

The SiC layer 2 preferably has a thickness of 0.1 μm to 5 μm, more preferably 0.5 μm to 1.5 μm, and even more preferably 0.7 μm to less than 1.0 μm (for example, 0.9 μm or less). By setting the thickness of the SiC layer 2 to 0.1 μm or more, more preferably 0.5 μm or more, and even more preferably 0.7 μm or more, the quality of the crystals of the SiC layer 2 can be further improved. As a result, the quality of the crystals of the nitride semiconductor layer 4 formed on the SiC layer 2 can be improved. Also, by setting the thickness of the SiC layer 2 to 5 μm or less, more preferably 1.5 μm or less, and even more preferably less than 1 μm (for example, 0.9 μm or less), the heat dissipation of the semiconductor device can be improved. The SiC layer 2 may contain intentionally doped n-type impurities (for example, N (nitrogen) or P (phosphorus)) to adjust its conductivity.

The bonding layer 3 is formed on the principal surface 1a of the diamond substrate 1. The bonding layer 3 is formed between the diamond substrate 1 and the SiC layer 2. The bonding layer 3 has a thickness of, for example, 1 nm to 10 nm.

The nitride semiconductor layer 4 is formed on the principal surface 2a of the SiC layer 2. The nitride semiconductor layer 4 includes multiple layers with different components, for example, InₓAl_{y}Ga_{1-x-y}N (0≤x≤1, 0≤y≤1, 0≤x+y≤1), and has an arbitrary layered structure. As an example, in cases where the semiconductor substrate is used to fabricate a semiconductor device including a HEMT, the nitride semiconductor layer 4 includes a heterostructure of AlGaN (aluminum gallium nitride) layer/GaN layer. The principal surface 4a of the nitride semiconductor layer 4 faces upward in FIG. 1.

When using the semiconductor substrate NS1 for power applications (applications in integrated circuits), it is preferable for the semiconductor substrate NS1 to have the following first configuration. In the first configuration, the diamond substrate 1 is semi-insulating or insulating. Specifically, the diamond substrate 1 has a resistivity of 5×10\hat{ }3 Ω·cm to 1×10\hat{ }16 Ω·cm. In the first configuration, the SiC layer 2 is conductive and preferably has an electron concentration of 1×10\hat{ }15 cm\hat{ }−3 to 1×10\hat{ }21 cm\hat{ }−3, more preferably 1×10\hat{ }18 cm\hat{ }−3 to 1×10\hat{ }21 cm\hat{ }−3.

Generally, in semiconductor devices for high-frequency applications, it is important to suppress the loss of high-frequency signals when high-frequency voltage is applied to the gate electrode of the transistor or the anode electrode of the diode. The main cause of this high-frequency signal loss is the parasitic capacitance and parasitic resistance of the semiconductor device. When the parasitic capacitance of the semiconductor device is large, and there are parasitic resistance components in parallel with the parasitic capacitance, these parasitic elements contribute to the loss of high-frequency signals and hinder the high-speed operation of the semiconductor device. To suppress the loss of high-frequency signals, it is effective to reduce the aforementioned parasitic elements.

Therefore, when using the semiconductor substrate NS1 for high-frequency applications, it is preferable for the semiconductor substrate NS1 to have the following second or third configuration.

In the second configuration, the parasitic elements are reduced by thickening the nitride semiconductor layer 4. The details of the second configuration will be explained in the fourth embodiment.

In the third configuration, the parasitic elements are reduced by making both the diamond substrate 1 and the SiC layer 2 semi-insulating or insulating. In the third configuration, the diamond substrate 1 has a resistivity of 5×10\hat{ }3 Ω·cm to 1×10\hat{ }16 Ω·cm. The SiC layer 2 has a resistivity of 1×10\hat{ }3 Ω·cm to 1×10\hat{ }16 Ω·cm. The nitride semiconductor layer 4 may have a thickness of 0.5 μm to less than 6 μm.

Next, the manufacturing method of semiconductor substrate NS1 is explained.

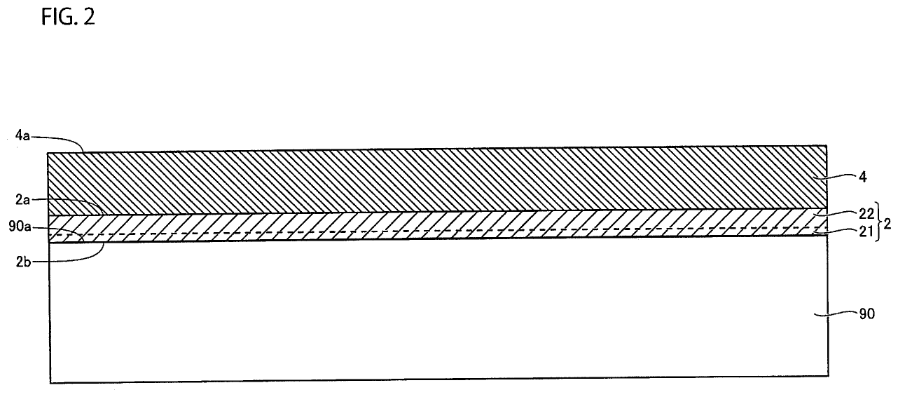

FIGS. 2 to 9 show the cross-sectional views of the manufacturing method of semiconductor substrate NS1 in the first embodiment of the present invention.

Referring to FIG. 2, an Si substrate 90 is prepared. The Si substrate 90 is, for example, made of p-type Si. The principal surface 90a of the Si substrate 90 faces upwards in FIG. 2. The surface orientation of the principal surface 90a of the Si substrate 90 is, for example, the (111) surface. The surface orientation of the principal surface 90a of the Si substrate 90 may be the (100) surface or the (110) surface. The Si substrate 90 has, for example, a diameter of 6 inches and a thickness of 1000 μm.

A monocrystalline SiC layer 2 is formed on the principal surface 90a of the Si substrate 90. The principal surface 2a of the SiC layer 2 faces upwards in FIG. 2, and the principal surface 2b of the SiC layer 2 faces downwards in FIG. 2. The SiC layer 2 may be formed by homoepitaxial growth of SiC on a base layer of SiC obtained by carbonizing the principal surface 90a of the Si substrate 90 using MBE, CVD (Chemical Vapor Deposition), or LPE (Liquid Phase Epitaxy). In this case, the SiC layer 2 includes a SiC layer 21 formed by carbonization and a SiC layer 22 epitaxially grown on the base SiC layer 21. The carbon (C) concentration of SiC layer 21 and SiC layer 22 are different from each other.

The SiC layer 2 may also be formed by heteroepitaxial growth on the principal surface 90a of the Si substrate 90 (or with a buffer layer in between). Whether the SiC layer 2 is formed on the principal surface 90a of the Si substrate 90 by carbonization, homoepitaxial growth, or heteroepitaxial growth, the SiC layer 2 has a 3C crystal structure.

A nitride semiconductor layer 4 is formed on the principal surface 2a of the SiC layer 2. The nitride semiconductor layer 4 is formed by heteroepitaxial growth on the principal surface 2a of the SiC layer 2 using, for example, the CVD method. Thus, there are no traces of bonding (such as an amorphous layer or an SiO₂ layer continuous to each of the SiC layer 2 and the nitride semiconductor layer 4) between the SiC layer 2 and the nitride semiconductor layer 4. The nitride semiconductor layer 4 includes a principal surface 4a. The principal surface 4a of the nitride semiconductor layer 4 faces upwards in FIG. 2.

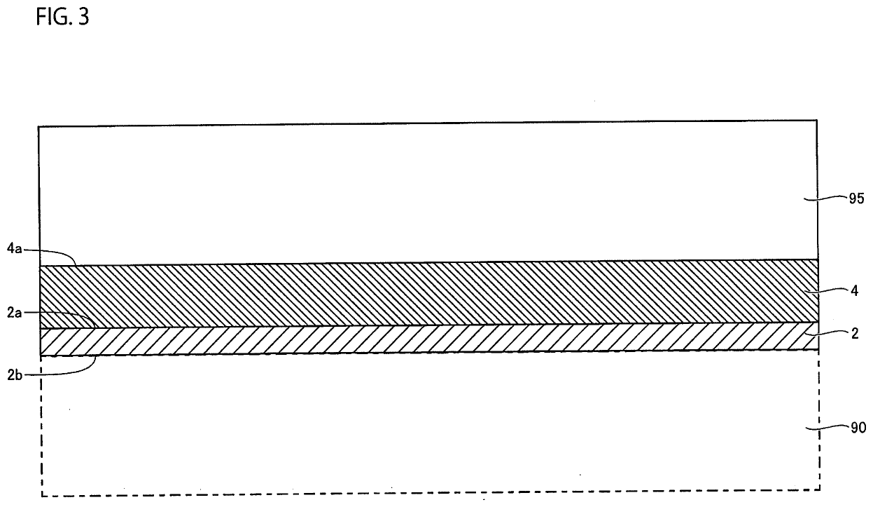

Referring to FIG. 3, a support substrate 95 is fixed to the principal surface 4a of the nitride semiconductor layer 4. The support substrate 95 plays a role in holding the SiC layer 2 and the nitride semiconductor layer 4 during the subsequent bonding. The support substrate 95 is made of any material.

The Si substrate 90 is selectively etched to remove the entire Si substrate 90 from the SiC layer 2 (in FIG. 3, the removed Si substrate 90 is indicated by a dashed line). After removing the Si substrate 90, the principal surface 2b of the SiC layer 2 is exposed.

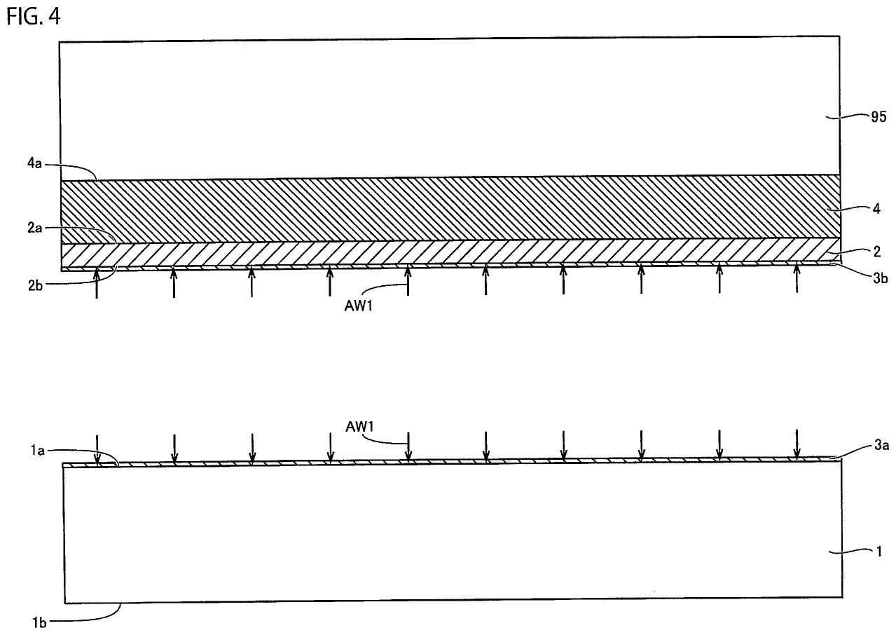

Referring to FIG. 4, a diamond substrate 1 is prepared. The principal surface 1a of the diamond substrate 1 faces upwards in FIG. 4, and the principal surface 1b of the diamond substrate 1 faces downwards in FIG. 4. The principal surface 1a of the diamond substrate 1 and the principal surface 2b of the SiC layer 2 are bonded together. In FIG. 4, the principal surface 2b of the SiC layer 2 faces downwards. To ensure firm contact to the principal surface 1a of the diamond substrate 1, the arithmetic average roughness Ra of the principal surface 2b of the SiC layer 2 is preferably greater than 0 and 1 nm or less, more preferably greater than 0 and 0.5 nm or less. Also, if the size of the Si substrate 90 is 4 inches or more, the warpage of the principal surface 2b of the SiC layer 2 is preferably greater than 0 and 50 μm or less. To further improve the bonding condition, the principal surface 2b of the SiC layer 2 may be processed by CMP to improve the arithmetic average roughness Ra of the principal surface 2b of the SiC layer 2.

A bonding interlayer (not shown) may be placed between the principal surface 1a of the diamond substrate 1 and the principal surface 2b of the SiC layer 2, and then the principal surface 1a of the diamond substrate 1 and the principal surface 2b of the SiC layer 2 may be bonded together. This bonding interlayer is made of any material and plays a role in improving the bonding strength between the diamond substrate 1 and the SiC layer 2.

Any method can be used for bonding the principal surface 1a of the diamond substrate 1 and the principal surface 2b of the SiC layer 2, and surface activation bonding is preferable. When using surface activation bonding, energy particles are irradiated on each of the principal surface 1a of the diamond substrate 1 and the principal surface 2b of the SiC layer 2 as indicated by arrow AW1 under reduced pressure of 1×10\hat{ }−5 Pa or less, preferably 1×10\hat{ }−6 Pa or less, and at room temperature (for example, a temperature of 10° C. to 30° C.). This removes adsorbed substances such as gas, water, organic materials, or oxygen from each of the principal surface 1a of the diamond substrate 1 and the principal surface 2b of the SiC layer 2. The energy particles consist of, for example, ions, Ar (argon), Kr (krypton), or Ne (neon) neutral atoms, or cluster ions, and are preferably made of Ar.

When energy particles are irradiated onto each of the principal surface 1a of the diamond substrate 1 and the principal surface 2b of the SiC layer 2, amorphous layers 3a and 3b, each having a thickness greater than 0 and less than or equal to 5 nm, appear on each of these surfaces, respectively. The amorphous layer 3a (an example of the first amorphous layer) results from the amorphization of diamond on the principal surface 1a of the diamond substrate 1 due to the collision of energy particles. The amorphous layer 3a is continuous with the diamond substrate 1, causing the principal surface 1a of the diamond substrate 1 to slightly recede towards the principal surface 1b. The amorphous layer 3b (an example of the second amorphous layer) results from the amorphization of SiC on the principal surface 2a of the SiC layer 2 due to the collision of energy particles. The amorphous layer 3b is continuous with the SiC layer 2, causing the principal surface 2b of the SiC layer 2 to slightly recede towards the principal surface 2a.

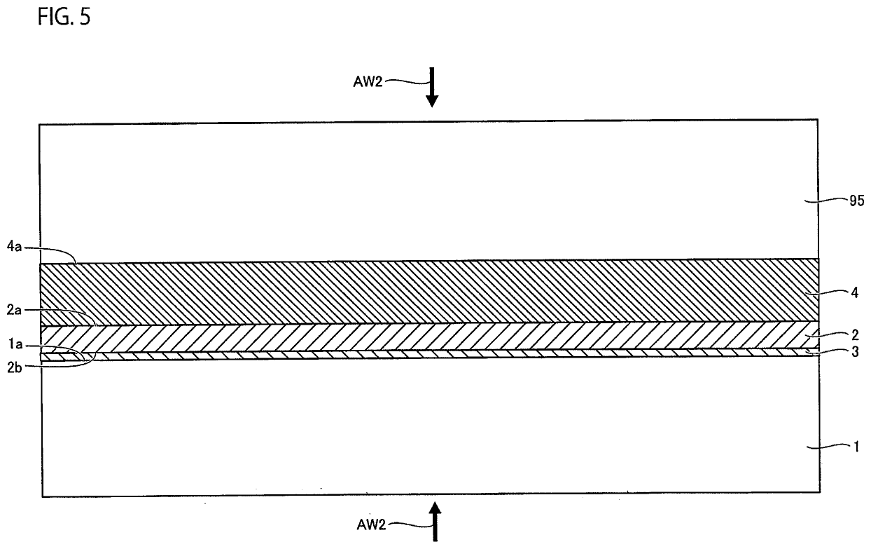

Referring to FIG. 5, the amorphous layers 3a and 3b are brought into contact with each other as indicated by arrow AW2. This results in the bonding of the principal surface 1a of the diamond substrate 1 and the principal surface 2b of the SiC layer 2, revealing the bonding layer 3.

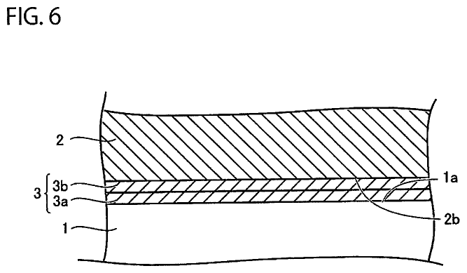

Referring to FIG. 6, the bonding layer 3 is a trace of the bonding between the diamond substrate 1 and the SiC layer 2. Thus, if the diamond substrate 1 and the SiC layer 2 are not bonded, the bonding layer 3 does not appear. The composition of the bonding layer 3 depends on the bonding method. When using the surface activation bonding method described above, the bonding layer 3 includes both the amorphous layers 3a and 3b. The amorphous layer 3a contains carbon and is primarily composed of carbon. It is formed on the principal surface 1a of the diamond substrate 1. The amorphous layer 3b contains carbon and silicon, with carbon and silicon being its main components. The amorphous layer 3b is formed between the amorphous layer 3a and the principal surface 2a of the SiC layer 2. The amorphous layers 3a and 3b can be observed by transmission electron microscopy (TEM) or similar methods. The bonding layer 3 contains silicon and carbon, as well as elements that were present in the atmosphere during bonding.

After bonding the diamond substrate 1 and the SiC layer 2, a heat treatment can be performed on the bonding layer 3. This can improve the strength of the bonding layer 3.

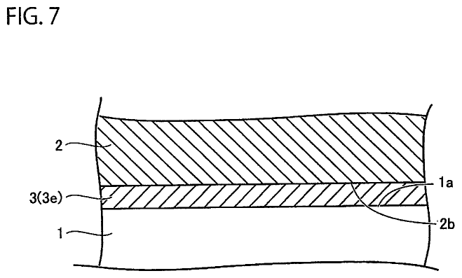

FIG. 7 is a partial cross-sectional view showing the configuration of the bonding part 3 after performing heat treatment on the bonding layer 3 when bonding using the surface activation method in the first embodiment of the present invention.

Referring to FIG. 7, if heat treatment is performed on the bonding layer 3 at a temperature of 1000° C. or higher but below the melting point of silicon, atoms contained in the amorphous layers 3a and 3b inside the bonding layer 3 recrystallize. As a result, the bonding layer 3 may contain a polycrystalline layer 3e. The polycrystalline layer 3e includes, at least, polycrystalline grains of SiC and is mainly composed of these polycrystalline grains of SiC. The polycrystalline layer 3e may further include polycrystalline grains containing atoms of the energy particles used during bonding.

If only some of the atoms contained in the amorphous layers 3a and 3b within the bonding layer 3 recrystallize due to heat treatment, the bonding layer 3 may include both the polycrystalline layer 3e and at least one of the amorphous layers 3a and 3b. If all the atoms contained in the amorphous layers 3a and 3b within the bonding layer 3 recrystallize due to heat treatment, the bonding layer 3 does not include the amorphous layers 3a and 3b, and the entire bonding layer 3 may consist of the polycrystalline layer 3e.

Since the carbon atom density inside the diamond substrate 1 is higher than the carbon atom density inside the SiC layer 2, the bonding layer 3 includes a concentration decreasing region 3f. The concentration decreasing region 3f is an area where the carbon atom density decreases monotonically from the diamond substrate 1 to the SiC layer 2 (along the thickness direction). When the diamond substrate 1 and the SiC layer 2 are bonded, the concentration decreasing region 3f occurs within the bonding layer 3 over a wider range compared to when the SiC layer is epitaxially grown on the diamond substrate. Specifically, the concentration decreasing region 3f has a thickness of 2 nm or more. The concentration decreasing region 3f occurs regardless of whether the bonding layer 3 includes the amorphous layers 3a and 3b and whether it includes the polycrystalline layer 3e.

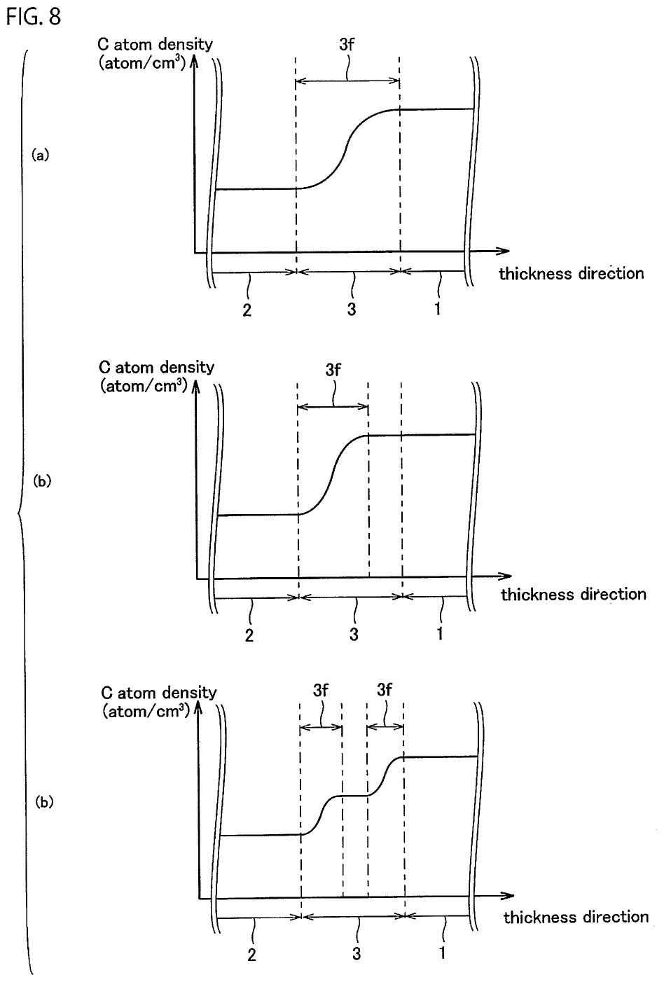

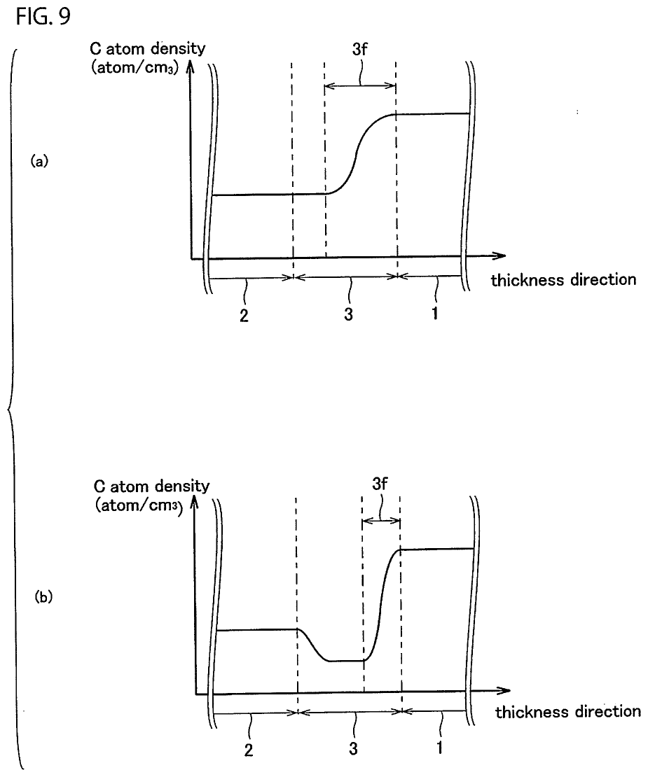

FIGS. 8 and 9 are diagrams showing the carbon atom density along the thickness direction in the bonding layer 3.

Referring to FIGS. 8 and 9, the carbon atom density along the thickness direction in the bonding layer 3 changes depending on the presence or absence of the bonding intermediate layer and the carbon atom density inside the bonding intermediate layer.

If the principal surface 1a of the diamond substrate 1 and the principal surface 2b of the SiC layer 2 are directly bonded, there is no bonding intermediate layer between the diamond substrate 1 and the SiC layer 2. In the absence of a bonding intermediate layer, the carbon atom density along the thickness direction in the bonding layer 3 is as shown in FIG. 8(a), where the concentration decreasing region 3f occurs throughout the bonding layer 3.

If there is a bonding intermediate layer with the same carbon atom density as the diamond substrate 1, the carbon atom density along the thickness direction in the bonding layer 3 is as shown in FIG. 8(b). In FIG. 8(b), the concentration decreasing region 3f occurs in the area including the interface between the SiC layer 2 and the bonding layer 3, but not at the interface between the diamond substrate 1 and the bonding layer 3.

If there is a bonding intermediate layer with a carbon atom density lower than that of the diamond substrate 1 but higher than that of the SiC layer 2, the carbon atom density along the thickness direction in the bonding layer 3 is as shown in FIG. 8(c). In FIG. 8(c), there are two concentration decreasing regions 3f, each occurring in the area including the interface between the diamond substrate 1 and the bonding layer 3, and the area including the interface between the SiC layer 2 and the bonding layer 3.

If there is a bonding intermediate layer with the same carbon atom density as the SiC layer 2, the carbon atom density along the thickness direction in the bonding layer 3 is as shown in FIG. 9(a). In FIG. 9(a), the concentration decreasing region 3f occurs in the area including the interface between the diamond substrate 1 and the bonding layer 3, but not at the interface between the SiC layer 2 and the bonding layer 3.

If there is a bonding intermediate layer with a carbon atom density lower than that of the SiC layer 2, the carbon atom density along the thickness direction in the bonding layer 3 is as shown in FIG. 9(b). In FIG. 9(b), the concentration decreasing region 3f occurs in the area including the interface between the diamond substrate 1 and the bonding layer 3. In the area including the interface between the SiC layer 2 and the bonding layer 3, the carbon atom density increases monotonically from the diamond substrate 1 to the SiC layer 2 (along the thickness direction).

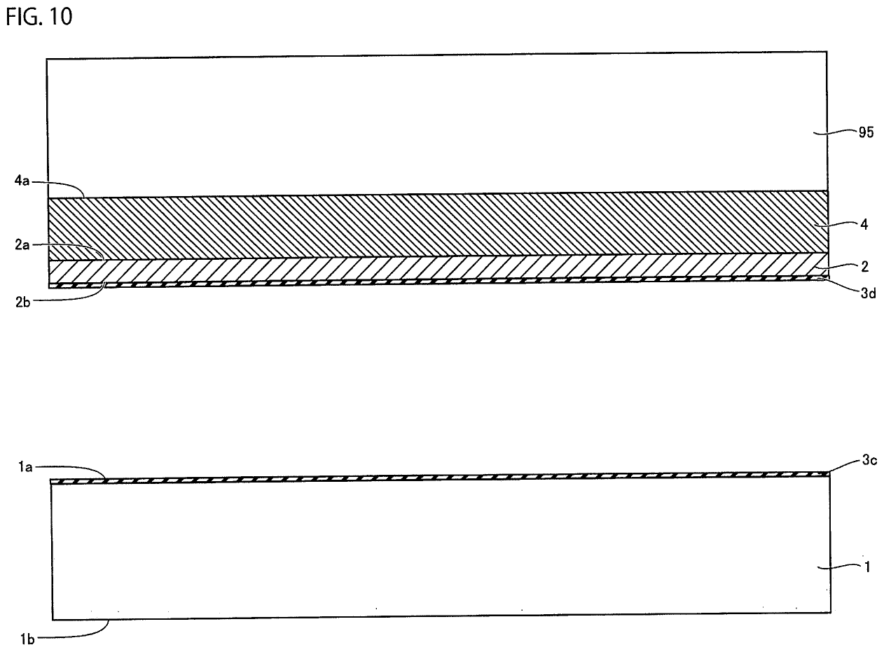

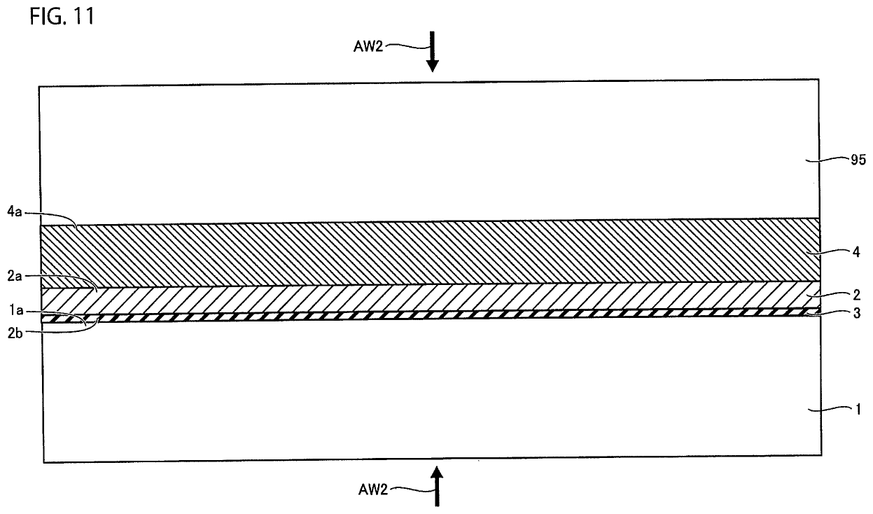

Referring to FIG. 10, hydrophilic bonding may be used as the bonding method between the principal surface 1a of the diamond substrate 1 and the principal surface 2b of the SiC layer 2, instead of surface activation bonding. Hydrophilic bonding is also called fusion bonding or silicon direct bonding (SDB). When using hydrophilic bonding, an SiO₂ layer 3c is formed on the principal surface 1a of the diamond substrate 1 using, for example, the CVD (Chemical Vapor Deposition) method. An SiO₂ layer 3d is formed on the principal surface 2b of the SiC layer 2. The SiO₂ layer 3d may be formed by forming an SiO₂ layer 3d on the principal surface 2b of the SiC layer 2 with the CVD method, or by forming an Si layer on the principal surface 2b of the SiC layer 2 and thermally oxidizing the Si layer, or by thermally oxidizing the principal surface 2b of the SiC layer 2. Both the SiO₂ layer 3c and the SiO₂ layer 3d are subjected to hydrophilization. Referring to FIG. 11, as indicated by arrow AW2, the SiO₂ layer 3c and the SiO₂ layer 3d are brought into contact with each other. This results in the bonding of the principal surface 1a of the diamond substrate 1 and the principal surface 2b of the SiC layer 2, revealing the bonding layer 3.

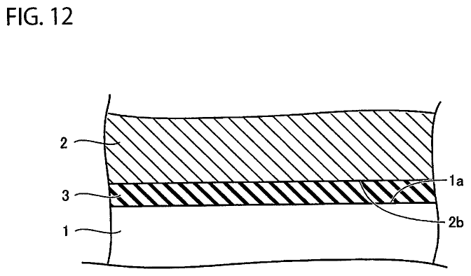

Referring to FIG. 12, when using the hydrophilic bonding method described above, the bonded SiO₂ layers 3c and 3d that is integrated result in a bonding layer 3 after bonding. The bonding layer 3 contains SiO₂.

The thermal conductivity of the SiO₂ layer is relatively low. The bonding layer 3, when using surface activation bonding, does not contain the SiO₂ layer. From the perspective of ensuring high thermal conductivity, using surface activation bonding is preferable.

Since both SiC and diamond are group IV semiconductors, they have high bonding affinity. Therefore, good bonding is achieved regardless of the bonding method.

The formation of the 3C-type monocrystalline SiC layer 2 on the principal surface 1a of the diamond substrate 1 is a trace of the bonding between the diamond substrate 1 and the SiC layer 2.

When the diamond substrate 1 is monocrystalline, the fact that the surface orientation of the bonding surface of the diamond substrate 1 and the bonding surface of the SiC layer 2 differ, or that there is a rotational misalignment between the surface orientations of the bonding surfaces of the diamond substrate 1 and the SiC layer 2, is a trace of the bonding between the monocrystalline diamond substrate 1 and the SiC layer 2. It is not easy to bond the monocrystalline diamond substrate 1 and the SiC layer 2 with identical surface orientations of their bonding surfaces. Even if it were possible to bond them with identical surface orientations, a rotational or tilting misalignment would occur during bonding.

Specifically, consider a scenario where the SiC layer 2 is a 3C-type monocrystalline and both the bonding surface of the SiC layer 2 (here, the principal surface 2b) and the bonding surface of the diamond substrate 1 (here, the principal surface 1a) have an approximately (111) surface orientation. In this case, when the bonding surfaces of the SiC layer 2 and the diamond substrate 1 are bonded together, the angle formed between the direction vector of the SiC layer 2's bonding surface and the direction vector of the diamond substrate 1's bonding surface, the angle formed between the [−111] direction vector of the SiC layer 2's bonding surface and the [−111] direction vector of the diamond substrate 1's bonding surface, the angle formed between the [1−11] direction vector of the SiC layer 2's bonding surface and the [1−11] direction vector of the diamond substrate 1's bonding surface, and the angle formed between the [11−1] direction vector of the SiC layer 2's bonding surface and the [11−1] direction vector of the diamond substrate 1's bonding surface, one of these four angles exceeds twice the value A. This occurs due to misalignment between the surface orientations of the diamond substrate 1's bonding surface and the SiC layer 2's bonding surface.

The value A is the larger of the X-ray rocking curve full width at half maximum (FWHM) of the SiC layer 2's bonding surface and the X-ray rocking curve FWHM of the diamond substrate 1's bonding surface.

Each of these vectors is extracted by the following method: Using X-ray diffraction or EBSD (Electron BackScatter Diffraction) with a common sample reference axis for both the SiC layer 2's bonding surface and the diamond substrate 1's bonding surface, pole figures for both surfaces are created. Then, from the pole figure of the SiC layer 2's bonding surface, points where the diffraction intensity is maximum at the diffraction peaks in the [111], [−111], [1−11], and [11−1] directions (a total of 4 points) are extracted. Similarly, from the pole figure of the diamond substrate 1's bonding surface, points where the diffraction intensity is maximum at the diffraction peaks in the [111], [−111], [1−11], and [11−1] directions (a total of 4 points) are extracted. Subsequently, from each of the 4 points obtained from the pole figure of the SiC layer 2's bonding surface, vectors in the [111], [−111], [1−11], and [11−1] directions of the SiC layer 2's bonding surface are extracted. Similarly, from each of the 4 points obtained from the pole figure of the diamond substrate 1's bonding surface, vectors in the [111], [−111], [1−11], and [11−1] directions of the diamond substrate 1's bonding surface are extracted.

Referring to FIG. 5 or 11, and FIG. 1, after bonding the diamond substrate 1 and the SiC layer 2, the entire support substrate 95 is removed. After the removal of the support substrate 95, the principal surface 4a of the nitride semiconductor layer 4 is exposed. Through these steps, the semiconductor substrate NS1 is obtained.

Generally, bulk SiC substrates have a 4H crystal structure and contain micropipes. It is difficult to manufacture bulk SiC substrates with a 3C crystal structure. It is also difficult to obtain bulk SiC substrates with a 3C crystal structure from the market. According to this embodiment, by forming the SiC layer 2 on the Si substrate 90 as a base, it is possible to obtain an SiC layer 2 with a 3C crystal structure. It is known that SiC layers with a 3C crystal structure do not contain micropipes. According to this embodiment, because the nitride semiconductor layer 4 is formed on the SiC layer 2 that does not contain micropipes, it is possible to avoid the deterioration of the crystal quality of the nitride semiconductor layer 4 due to micropipes. Furthermore, according to this embodiment, since it is not necessary to form the SiC layer 2 solely by carbonization, the SiC layer 2, which is the base for the nitride semiconductor layer 4, can be made sufficiently thick. As a result, it is possible to improve the crystal quality of the nitride semiconductor layer 4 and manufacture high-power devices with high heat dissipation.

Additionally, according to this embodiment, because the SiC layer 2 has a 3C crystal structure, it is possible to effectively prevent the occurrence of leak currents to the nitride semiconductor layer 4 compared to SiC layers with a 4H crystal structure. As a result, it is possible to improve the performance of the device. This will be explained below.

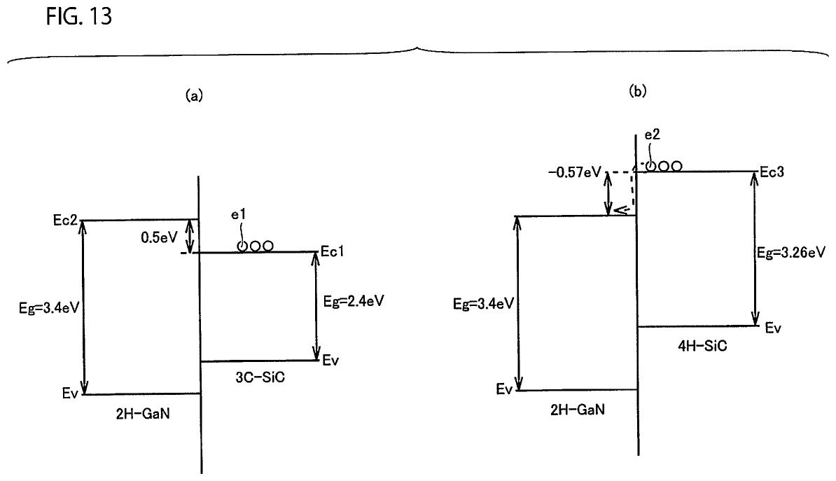

FIG. 13 is a comparison diagram between the band lineups of 3C—SiC/GaN and 4H—SiC/GaN. In FIG. 13, the bandgap is denoted as Eg, the energy at the top of the valence band is denoted as Ev, and the energy at the bottom of the conduction band is denoted as Ec1, Ec2, or Ec3.

Referring to FIG. 13(a), the energy Ec1 at the bottom of the conduction band of 3C—SiC (SiC with a 3C crystal structure) is 0.5 eV lower than the energy Ec2 at the bottom of the conduction band of 2H—GaN (GaN with a 2H crystal structure). Therefore, electrons e1 originating from donors in the 3C—SiC layer do not distribute in the 2H—GaN layer. This indicates that electrons in the 3C—SiC layer are less likely to leak into the nitride semiconductor layer.

Referring to FIG. 13(b), on the other hand, the energy Ec3 at the bottom of the conduction band of 4H—SiC (SiC with a 4H crystal structure) is 0.57 eV higher than the energy Ec2 at the bottom of the conduction band of 2H—GaN. Therefore, electrons e2 originating from donors in the 4H—SiC layer distribute in the 2H—GaN layer, as indicated by the dashed arrow. This indicates that electrons in the 4H—SiC layer are more likely to leak into the nitride semiconductor layer.

The band lineup shown in FIG. 13(a) is also presented in the literature (“Valence and conduction band alignment at ScN interfaces with 3C—SiC (111) and 2H—GaN (0001),” Appl. Phys. Lett., 105, 081606 (2014)). The band lineup shown in FIG. 13(b) is also presented in the literature (“Demonstration of Common-Emitter Operation in AlGaN/SiC Heterojunction Bipolar Transistors,” IEEE Electron Device Lett., 31, 942 (2010)).

### [Variation of the Manufacturing Method for the First Embodiment]

Next, a variation of the manufacturing method for the semiconductor substrate NS1 in the first embodiment shown in FIG. 1 is explained. The first embodiment described a manufacturing method where the nitride semiconductor layer 4 is formed on the principal surface 2a of the SiC layer 2 before bonding the diamond substrate 1 and the SiC layer 2. This variation describes a manufacturing method where the nitride semiconductor layer 4 is formed on the principal surface 2b of the SiC layer 2 after bonding the diamond substrate 1 and the SiC layer 2.

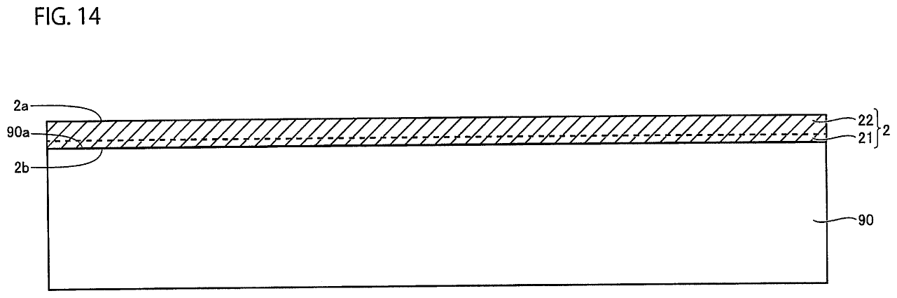

FIGS. 14 to 17 are cross-sectional diagrams showing the first variation of the manufacturing method for the semiconductor substrate NS1 in the first embodiment of the present invention.

Referring to FIG. 14, similar to the step shown in FIG. 2, the Si substrate 90 is prepared, and a single-crystal SiC layer 2 is formed on the principal surface 90a of the Si substrate 90. The principal surface 2a of the SiC layer 2 faces upwards in FIG. 14, and the principal surface 2b faces downwards.

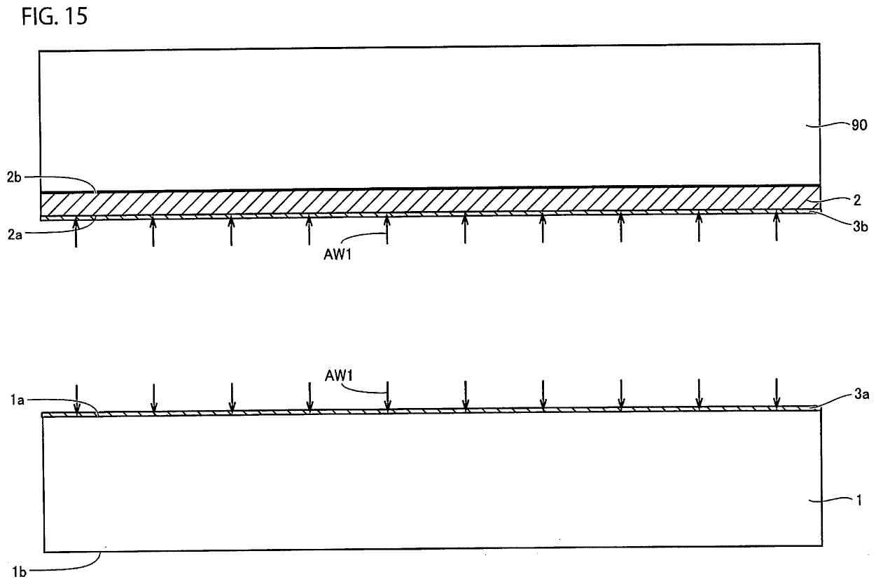

Referring to FIG. 15, the diamond substrate 1 is prepared. The principal surface 1a of the diamond substrate 1 faces upwards in FIG. 15, and the principal surface 1b faces downwards. Using surface-activated bonding, the principal surface 1a of the diamond substrate 1 and the principal surface 2a of the SiC layer 2 are bonded. Specifically, similar to the step shown in FIG. 4, energy particles are irradiated onto each of the principal surface 1a of the diamond substrate 1 and the principal surface 2a of the SiC layer 2, as indicated by arrow AW1. Amorphous layers 3a and 3b appear on each of the principal surface 1a of the diamond substrate 1 and the principal surface 2a of the SiC layer 2, respectively.

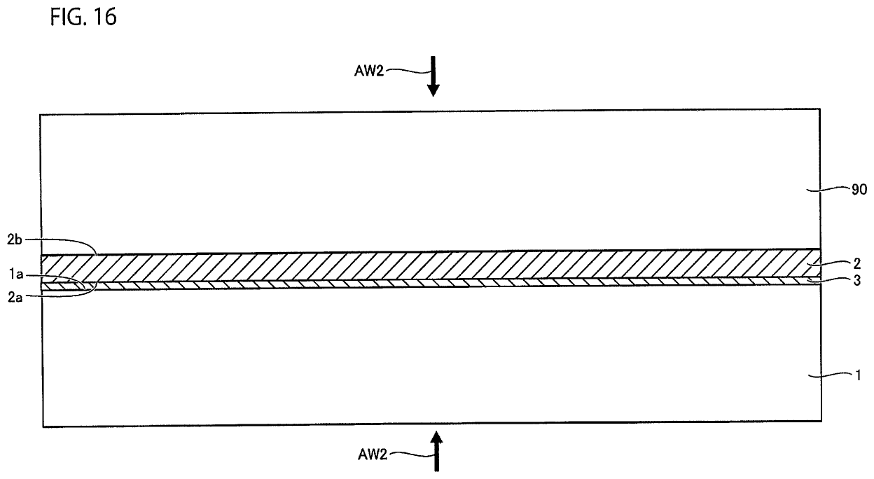

Referring to FIG. 16, similar to the step shown in FIG. 5, the amorphous layers 3a and 3b are brought into contact with each other, as indicated by arrow AW2. This results in the bonding of the principal surface 1a of the diamond substrate 1 and the principal surface 2a of the SiC layer 2, and the bonding layer 3 appears. Note that any bonding method may be used, including hydrophilic bonding.

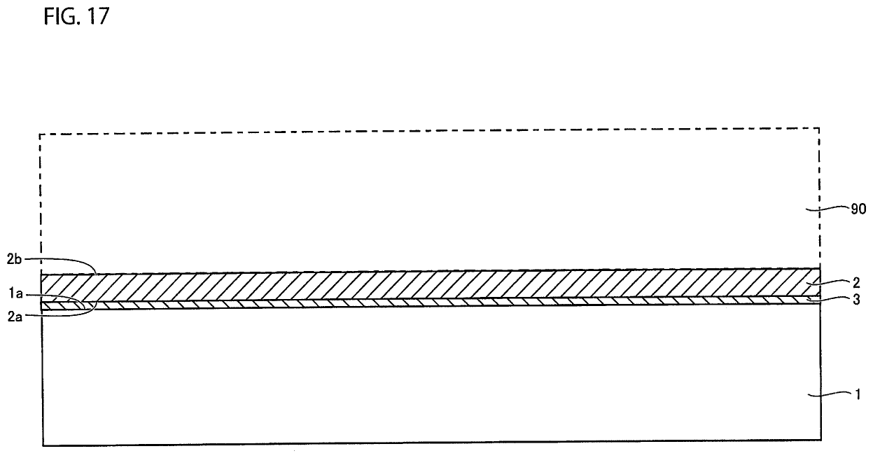

Referring to FIG. 17, similar to the step shown in FIG. 3, the Si substrate 90 is selectively etched to remove the entire Si substrate 90 from the SiC layer 2 (in FIG. 17, the removed Si substrate 90 is shown in dashed lines). After the removal of the Si substrate 90, the principal surface 2b of the SiC layer 2 is exposed.

Referring to FIG. 1, subsequently, similar to the step shown in FIG. 2, the nitride semiconductor layer 4 is formed on the principal surface 2b of the SiC layer 2. Through these steps, the semiconductor substrate NS1 is obtained. However, in the semiconductor substrate NS1 obtained in the first variation, the orientations of the principal surfaces 2a and 2b of the SiC layer 2 are reversed compared to the case in FIG. 1.

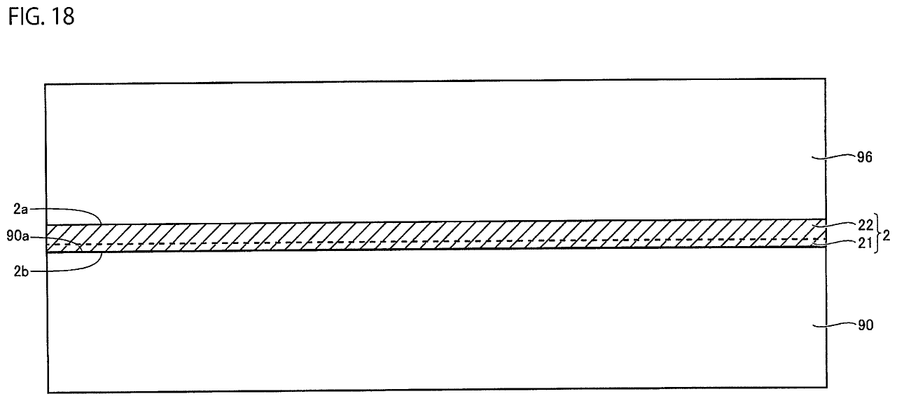

FIGS. 18 to 22 are cross-sectional diagrams showing the second variation of the manufacturing method for the semiconductor substrate NS1 in the first embodiment of the present invention.

Referring to FIG. 18, similar to the step shown in FIG. 2, the Si substrate 90 is prepared, and a single-crystal SiC layer 2 is formed on the principal surface 90a of the Si substrate 90. A support substrate 96 is fixed (attached) to the principal surface 2a of the SiC layer 2 using any method. The support substrate 96 serves to hold the SiC layer 2 during the subsequent bonding. The support substrate 96 is made of any material.

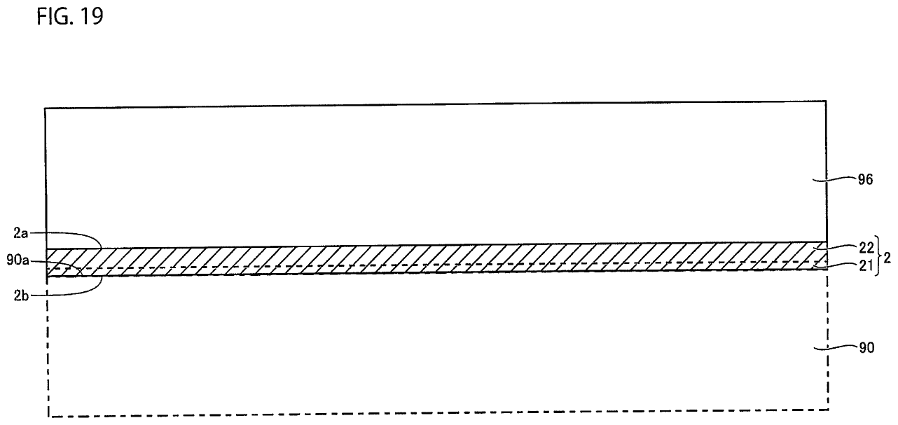

Referring to FIG. 19, the Si substrate 90 is selectively etched to remove the entire Si substrate 90 from the SiC layer 2 (in FIG. 19, the removed Si substrate 90 is shown in dashed lines). After the removal of the Si substrate 90, the principal surface 2b of the SiC layer 2 is exposed.

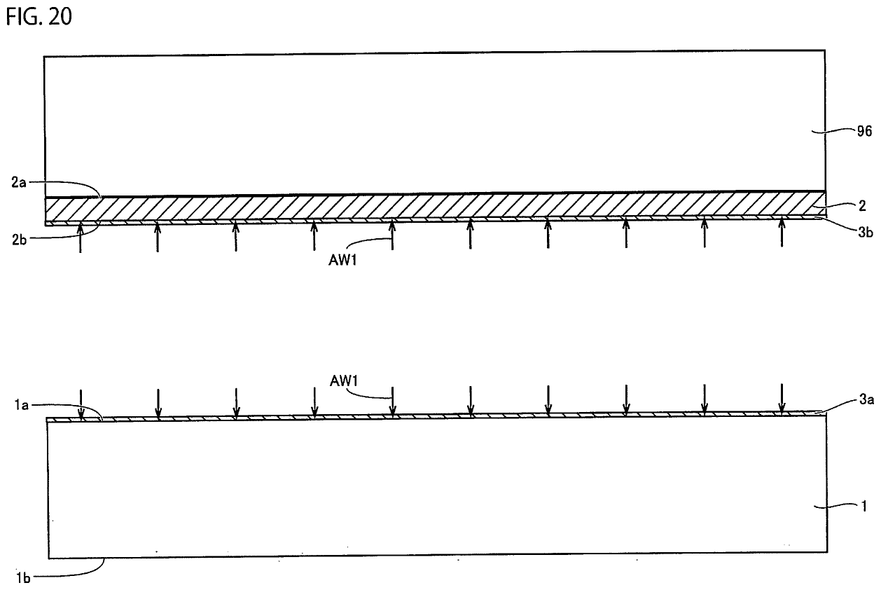

Referring to FIG. 20, the diamond substrate 1 is prepared. The principal surface 1a of the diamond substrate 1 faces upwards in FIG. 20, and the principal surface 1b faces downwards. Using surface-activated bonding, the principal surface 1a of the diamond substrate 1 and the principal surface 2b of the SiC layer 2 are bonded. Specifically, similar to the step shown in FIG. 4, energy particles are irradiated onto each of the principal surface 1a of the diamond substrate 1 and the principal surface 2b of the SiC layer 2, as indicated by arrow AW1. Amorphous layers 3a and 3b appear on each of the principal surface 1a of the diamond substrate 1 and the principal surface 2b of the SiC layer 2, respectively.

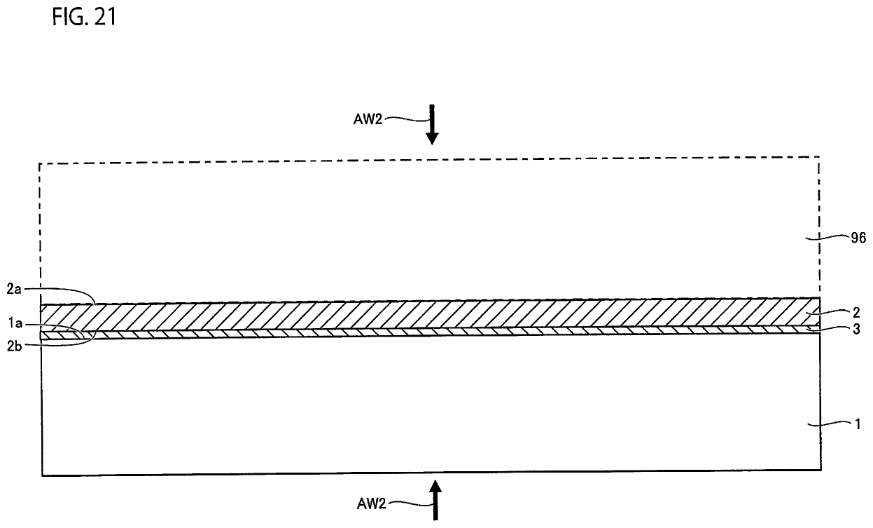

Referring to FIG. 21, similar to the step shown in FIG. 5, the amorphous layers 3a and 3b are brought into contact with each other, as indicated by arrow AW2. This results in the bonding of the principal surface 1a of the diamond substrate 1 and the principal surface 2b of the SiC layer 2, and the bonding layer 3 appears. Note that any bonding method may be used, including hydrophilic bonding. After bonding the diamond substrate 1 and the SiC layer 2, the entire support substrate 96 is removed (in FIG. 21, the removed support substrate 96 is shown in dashed lines). After the removal of the support substrate 96, the principal surface 2a of the SiC layer 2 is exposed.

Referring to FIG. 1, subsequently, similar to the step shown in FIG. 2, the nitride semiconductor layer 4 is formed on the principal surface 2a of the SiC layer 2. Through these steps, the semiconductor substrate NS1 is obtained.

Comparing the first and second variations described above, the principal surface of the SiC layer 2 that serves as the base for the nitride semiconductor layer 4 is the principal surface 2b in the first variation, and the principal surface 2a in the second variation. Generally, the atoms constituting the outermost surface of the principal surfaces 2a and 2b of the SiC layer 2 differ from each other. For example, the outermost surface of the principal surface 2a may be a Si face (surface composed of Si atoms), and the outermost surface of the principal surface 2b may be a C face (surface composed of C atoms). The electrical properties of the Si face and C face of the SiC layer 2 differ from each other. Therefore, by appropriately selecting the manufacturing method for the semiconductor substrate NS1, it is possible to appropriately set the electrical properties of the semiconductor substrate NS1.

### Second Embodiment

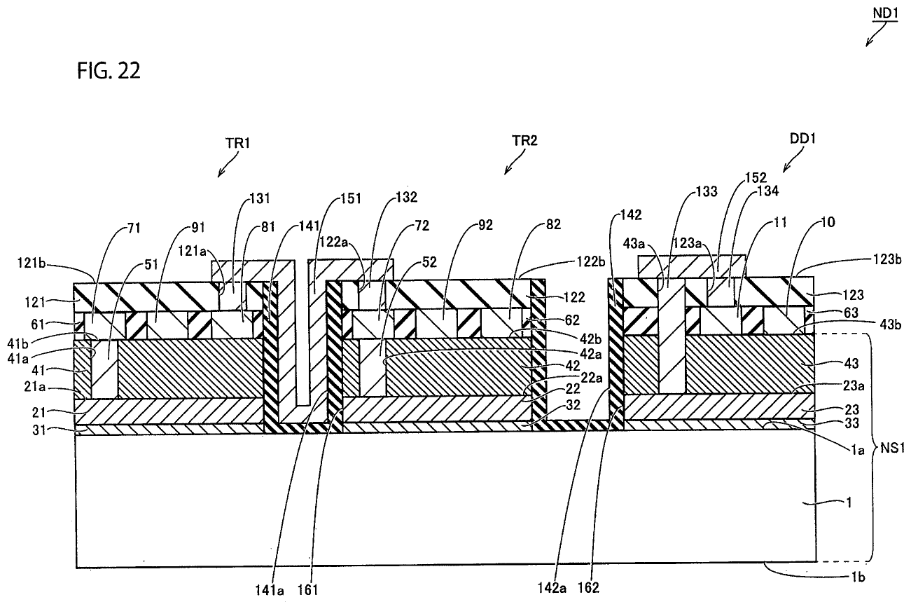

FIG. 22 is a cross-sectional diagram showing the configuration of the semiconductor device ND1 according to the second embodiment of the present invention.

Referring to FIG. 22, the semiconductor device ND1 (an example of a semiconductor device) in this embodiment is manufactured using the semiconductor substrate NS1 of the first embodiment and includes, as a device, transistors TR1 and TR2, and diode DD1. Each of transistors TR1 and TR2, and diode DD1 has a mesa structure. Transistor TR1 and transistor TR2 are separated from each other by trench 161. Transistor TR2 and diode DD1 are separated from each other by trench 162. Trenches 161 and 162 separate the bonding layer 3 into bonding layers 31 to 33, the SiC layer 2 into SiC layers 21 to 23, and the nitride semiconductor layer 4 into nitride semiconductor layers 41 to 43. SiC layers 21 to 23 are electrically insulated from each other. The potential of each of SiC layers 21 to 23 may be floating or fixed.

Transistor TR1, for example, serves as the low-voltage side switch in a half-bridge circuit and is made of a HEMT. Transistor TR1 includes a diamond substrate 1 (an example of a heat conductive layer), an SiC layer 21 (an example of a silicon carbide layer), a bonding layer 31 (an example of a bonding layer), a nitride semiconductor layer 41 (an example of a nitride semiconductor layer), a conductive layer 51 (an example of a conductive layer), an interlayer insulating layer 61, a source electrode 71 (an example of a first electrode), a drain electrode 81 (an example of a second electrode), a gate electrode 91, an interlayer insulating layer 121, and a conductive layer 131. On the principal surface 1a of the diamond substrate 1, the bonding layer 31, SiC layer 21, nitride semiconductor layer 41, interlayer insulating layer 61, and interlayer insulating layer 121 are stacked in this order.

The nitride semiconductor layer 41 includes a via hole 41a that extends from the principal surface 41b of the nitride semiconductor layer 41 to the SiC layer 21. The conductive layer 51 is formed inside the via hole 41a, electrically connecting the SiC layer 21 and the source electrode 71. The principal surface 41b of the nitride semiconductor layer 41 has formed on it the source electrode 71, the drain electrode 81, the gate electrode 91, and the interlayer insulating layer 61. The source electrode 71, the drain electrode 81, and the gate electrode 91 are formed on the side of the principal surface 21a of the SiC layer 21. The source electrode 71, the drain electrode 81, and the gate electrode 91 are formed spaced apart from each other. The source electrode 71 is electrically connected to the SiC layer 21. The source electrode 71 is grounded. The interlayer insulating layer 61 is formed to fill the spaces between the source electrode 71, the drain electrode 81, and the gate electrode 91. The interlayer insulating layer 121 covers the source electrode 71, the drain electrode 81, the gate electrode 91, and the interlayer insulating layer 61. The interlayer insulating layer 121 includes a via hole 121a that reaches the drain electrode 81. The conductive layer 131 is formed inside the via hole 121a, electrically connecting to the drain electrode 81.

Transistor TR2, for example, serves as the high-voltage side switch in a half-bridge circuit and is made of a HEMT. Transistor TR2 has a structure almost identical to that of transistor TR1. Transistor TR2 includes a diamond substrate 1 (an example of a heat conductive layer), an SiC layer 22 (an example of a silicon carbide layer), a bonding layer 32 (an example of a bonding layer), a nitride semiconductor layer 42 (an example of a nitride semiconductor layer), a conductive layer 52 (an example of a conductive layer), an interlayer insulating layer 62, a source electrode 72 (an example of a first electrode), a drain electrode 82 (an example of a second electrode), a gate electrode 92, an interlayer insulating layer 122, and a conductive layer 132. On the principal surface 1a of the diamond substrate 1, the bonding layer 32, SiC layer 22, nitride semiconductor layer 42, interlayer insulating layer 62, and interlayer insulating layer 122 are stacked in this order.

The nitride semiconductor layer 42 includes a via hole 42a that extends from the principal surface 42b of the nitride semiconductor layer 42 to the SiC layer 22. The conductive layer 52 is formed inside the via hole 42a, electrically connecting the SiC layer 22 and the source electrode 72. The principal surface 42b of the nitride semiconductor layer 42 has formed on it the source electrode 72, the drain electrode 82, the gate electrode 92, and the interlayer insulating layer 62. The source electrode 72, the drain electrode 82, and the gate electrode 92 are formed on the side of the principal surface 22a of the SiC layer 22. The source electrode 72, the drain electrode 82, and the gate electrode 92 are formed spaced apart from each other. The source electrode 72 is electrically connected to the SiC layer 22. A fixed potential is applied to the drain electrode 82. The interlayer insulating layer 62 is formed to fill the spaces between the source electrode 72, the drain electrode 82, and the gate electrode 92. The interlayer insulating layer 122 covers the source electrode 72, the drain electrode 82, the gate electrode 92, and the interlayer insulating layer 62. The interlayer insulating layer 122 includes a via hole 122a that reaches the source electrode 72. The conductive layer 132 is formed inside the via hole 122a, electrically connecting to the source electrode 72.

Diode DD1 is made of a Schottky barrier diode. Diode DD1 includes a diamond substrate 1 (an example of a heat conductive layer), an SiC layer 23 (an example of a silicon carbide layer), a bonding layer 33 (an example of a bonding layer), a nitride semiconductor layer 43 (an example of a nitride semiconductor layer), an interlayer insulating layer 63, a cathode electrode 10 (an example of a second electrode), an anode electrode 11 (an example of a first electrode), an interlayer insulating layer 123, and conductive layers 133 and 134, and a conductive layer 152. On the side of the principal surface 1a of the diamond substrate 1, the SiC layer 23, nitride semiconductor layer 43, interlayer insulating layer 63, interlayer insulating layer 123, and conductive layer 152 are stacked in this order.

On the principal surface 43b of the nitride semiconductor layer 43, the cathode electrode 10, the anode electrode 11, and the interlayer insulating layer 63 are formed. Both the cathode electrode 10 and the anode electrode 11 are formed on the side of the principal surface 23a of the SiC layer 23. The cathode electrode 10 and the anode electrode 11 are formed spaced apart from each other. The anode electrode 11 is electrically connected to the SiC layer 23. The interlayer insulating layer 63 is formed to fill the spaces between the cathode electrode 10 and the anode electrode 11. The interlayer insulating layer 123 covers the cathode electrode 10, the anode electrode 11, and the interlayer insulating layer 63. The interlayer insulating layers 123, 63, and the nitride semiconductor layer 43 each have a via hole 43a formed from the principal surface 123b of the interlayer insulating layer 123 to the SiC layer 23. The conductive layer 133 is formed inside the via hole 43a. The interlayer insulating layer 123 includes a via hole 123a reaching the anode electrode 11. The conductive layer 134 is formed inside the via hole 123a. The conductive layer 152 covers both conductive layers 133 and 134. The conductive layers 133, 152, and 134 (examples of a conductive layer) electrically connect the SiC layer 23 and the anode electrode 11.

Along the side and bottom surfaces of trench 161, an insulating layer 141 is formed. Along the side and bottom surfaces of trench 162, an insulating layer 142 is formed. A conductive layer 151 is formed on the principal surface 121b of the interlayer insulating layer 121, the principal surface 141a of the insulating layer 141, and the principal surface 122b of the interlayer insulating layer 122. The conductive layer 151 electrically connects the drain electrode 81 of transistor TR1 and the source electrode 72 of transistor TR2.

Note that the semiconductor device ND1 is an example of a device manufactured using the semiconductor substrate NS1. The device manufactured using the semiconductor substrate NS1 may have any configuration. In each of transistors TR1 and TR2, the drain electrode instead of the source electrode may be electrically connected to the SiC layer. In diode DD1, the cathode electrode 10 instead of the anode electrode 11 may be electrically connected to the SiC layer 23.

Next, the manufacturing method of the semiconductor device ND1 will be explained.

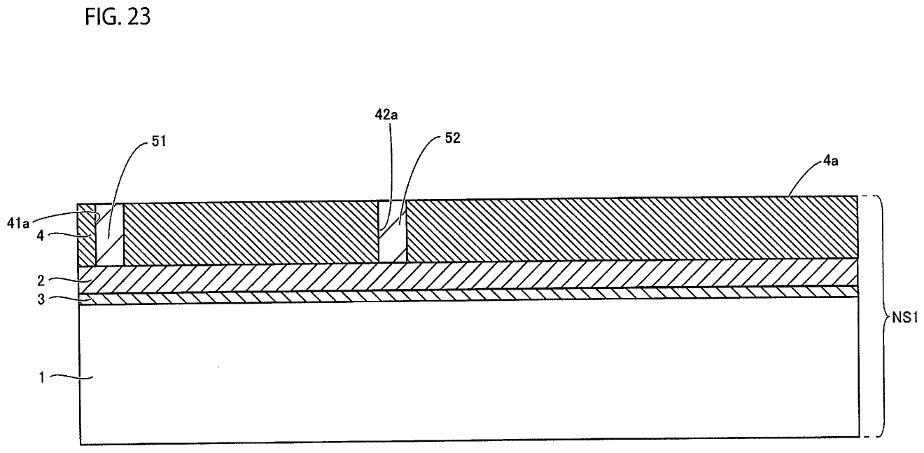

FIGS. 23 to 29 are cross-sectional diagrams showing the manufacturing method of the semiconductor device ND1 in the second embodiment of the present invention.

Referring to FIG. 23, the semiconductor substrate NS1 is prepared. Using standard photolithography and etching techniques, via holes 41a and 42a are formed in predetermined areas on the principal surface 4a of the nitride semiconductor layer 4. The bottom of each of the via holes 41a and 42a exposes the SiC layer 2. A conductive layer is formed inside each of the via holes 41a and 42a and on the principal surface 4a of the nitride semiconductor layer 4, and the excess conductive layer on the principal surface 4a is removed. Thus, conductive layers 51 and 52 are formed inside each of the via holes 41a and 42a, respectively.

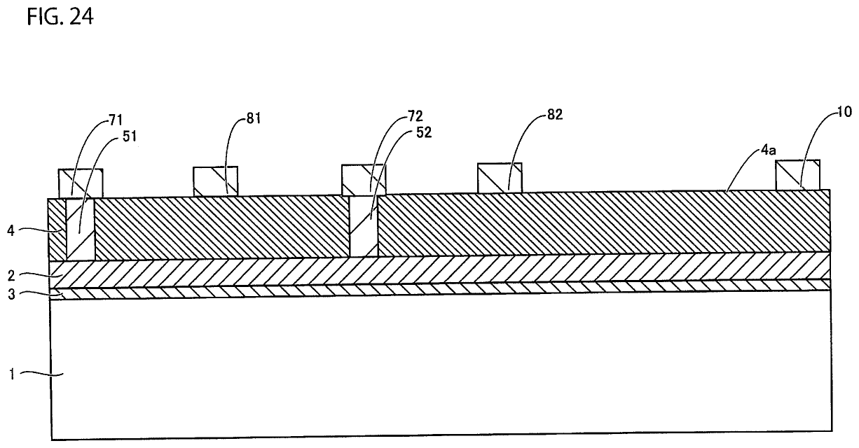

Referring to FIG. 24, by methods such as lift-off, the source electrodes 71 and 72, drain electrodes 81 and 82, and cathode electrode 10 are formed in predetermined areas on the principal surface 4a of the nitride semiconductor layer 4. At this time, each of the source electrodes 71 and 72 is formed in contact with the conductive layers 51 and 52, respectively. This electrically connects each of the source electrodes 71 and 72 to the SiC layer 2.

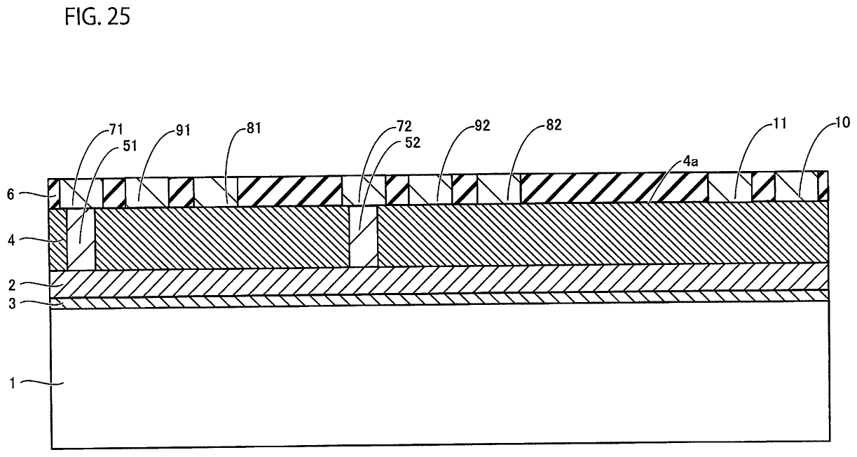

Referring to FIG. 25, by methods such as lift-off, the gate electrodes 91 and 92, and the anode electrode 11 are formed in predetermined areas on the principal surface 4a of the nitride semiconductor layer 4. An insulating layer is formed on the principal surface 4a of the nitride semiconductor layer 4 to cover the source electrodes 71 and 72, drain electrodes 81 and 82, gate electrodes 91 and 92, cathode electrode 10, and anode electrode 11. The excess insulating layer on top of the source electrodes 71 and 72, drain electrodes 81 and 82, gate electrodes 91 and 92, cathode electrode 10, and anode electrode 11 is removed. This forms the interlayer insulating layer 6 in areas on the principal surface 4a of the nitride semiconductor layer 4 excluding the source electrodes 71 and 72, drain electrodes 81 and 82, gate electrodes 91 and 92, cathode electrode 10, and anode electrode 11.

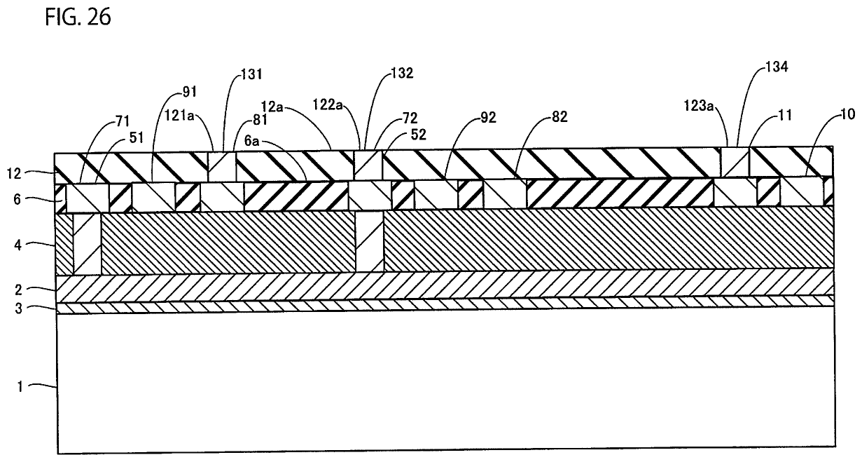

Referring to FIG. 26, the interlayer insulating layer 12 is formed on the principal surface 6a of the interlayer insulating layer 6. Using standard photolithography and etching techniques, via holes 121a, 122a, and 123a are formed in predetermined areas of the interlayer insulating layer 12. The bottom of each of the via holes 121a, 122a, and 123a exposes the drain electrode 81, the source electrode 72, and the anode electrode 11, respectively. A conductive layer is formed inside each of the via holes 121a, 122a, and 123a and on the principal surface 12a of the interlayer insulating layer 12. The excess conductive layer on the principal surface 12a is removed. This forms the conductive layers 131, 132, and 134 inside each of the via holes 121a, 122a, and 123a, respectively.

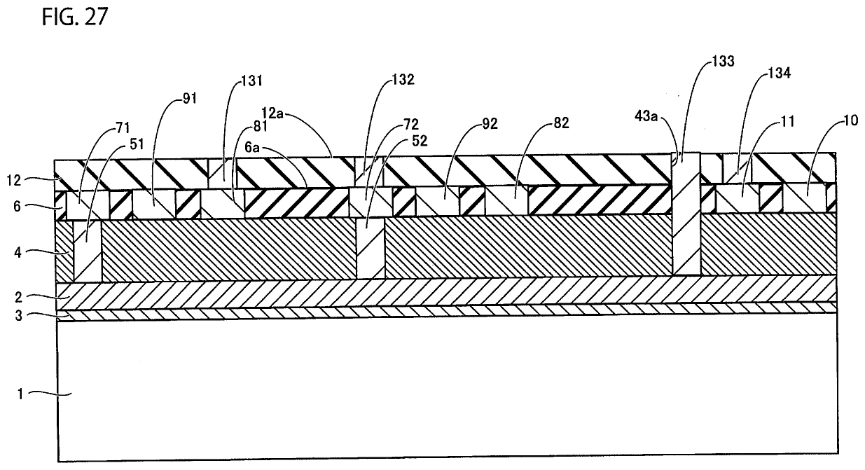

Referring to FIG. 27, using standard photolithography and etching techniques, the via hole 43a is formed in a predetermined area of the interlayer insulating layer 12. The bottom of the via hole 43a exposes the SiC layer 2. A conductive layer is formed inside the via hole 43a and on the principal surface 12a of the interlayer insulating layer 12. The excess conductive layer on the principal surface 12a is removed. This forms the conductive layer 133 inside the via hole 43a.

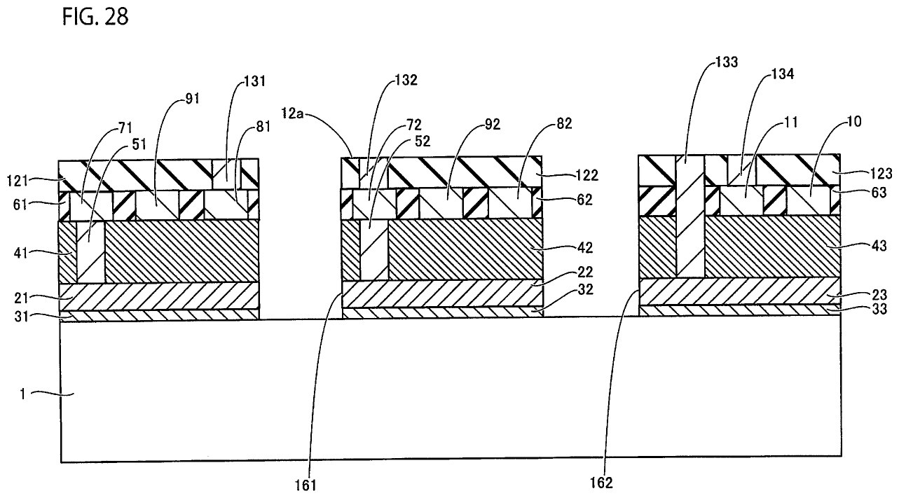

Referring to FIG. 28, using standard photolithography and etching techniques, trenches 161 and 162 are formed in predetermined areas of the interlayer insulating layer 12. The bottom of each of the trenches 161 and 162 exposes the diamond substrate 1. The formation of trenches 161 and 162 separates the bonding layer 3 into bonding layers 31 to 33, the SiC layer 2 into SiC layers 21 to 23, the nitride semiconductor layer 4 into nitride semiconductor layers 41 to 43, the interlayer insulating layer 6 into interlayer insulating layers 61 to 63, and the interlayer insulating layer 12 into interlayer insulating layers 121 to 123.

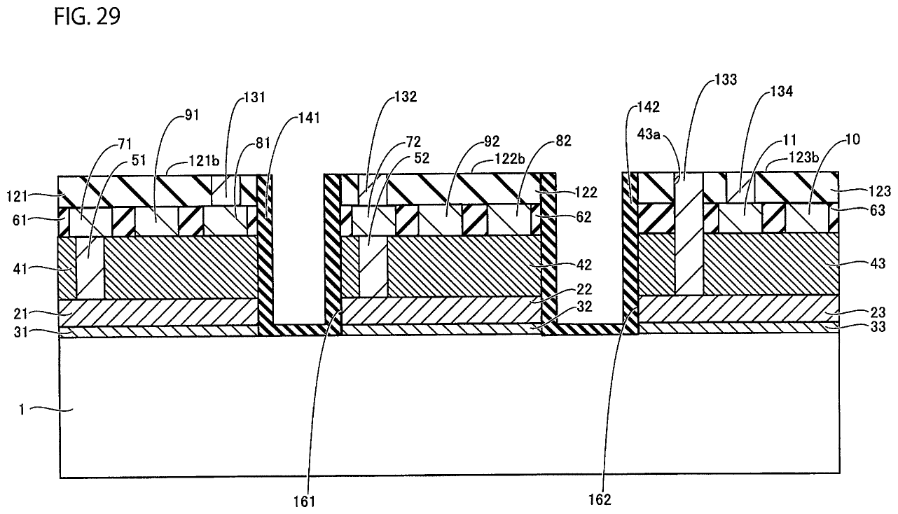

Referring to FIG. 29, an insulating layer is formed along the sides and bottom surfaces of each of the trenches 161 and 162, the principal surface 121b of the interlayer insulating layer 121, the principal surface 122b of the interlayer insulating layer 122, and the principal surface 123b of the interlayer insulating layer 123. The excess insulating layer on the principal surface 121b of the interlayer insulating layer 121, the principal surface 122b of the interlayer insulating layer 122, and the principal surface 123b of the interlayer insulating layer 123 is removed. This forms the insulating layers 141 and 142 along the sides and bottom surfaces of each of the trenches 161 and 162.

Referring to FIG. 22, a conductive layer is formed on the principal surface 141a of the insulating layer 141, the principal surface 142a of the insulating layer 142, the principal surface 121b of the interlayer insulating layer 121, the principal surface 122b of the interlayer insulating layer 122, and the principal surface 123b of the interlayer insulating layer 123. The excess conductive layer on the principal surface 121b of the interlayer insulating layer 121, the principal surface 122b of the interlayer insulating layer 122, the principal surface 123b of the interlayer insulating layer 123, and the principal surface 142a of the insulating layer 142 is removed. This forms the conductive layer 151 on the principal surface 121b of the interlayer insulating layer 121, the principal surface 141a of the insulating layer 141, and the principal surface 122b of the interlayer insulating layer 122. The conductive layer 152 is formed on the principal surface 123b of the interlayer insulating layer 123. The anode electrode 11 and the SiC layer 23 are electrically connected. Through these processes, the semiconductor device ND1 is obtained.

Note that configurations and manufacturing methods of the semiconductor device ND1 other than those described above are the same as those of the semiconductor substrate NS1 in the first embodiment and the semiconductor device ND1 in the second embodiment, so their explanation is not repeated.

According to this embodiment, it is possible to improve the withstand voltage of the devices included in the semiconductor device ND1, such as transistors TR1 and TR2, and diode DD1. Specifically, since the source electrode 71 of transistor TR1 and the SiC layer 21 are electrically connected and thus at the same potential. When transistor TR1 is off state, some of the electric field lines from the drain electrode 81 towards the gate electrode 91, which is adjacent to the drain electrode 81, are pulled towards the SiC layer 21. This relaxes the density of the electric field lines going from the drain electrode 81 to the gate electrode 91, relaxing the electric field between the gate electrode 91 and the drain electrode 81. As a result, the withstand voltage of transistor TR1 is improved. Similarly, since the source electrode 72 of transistor TR2 and the SiC layer 22 are at the same potential, the electric field between the drain electrode 82 and the gate electrode 92 is relaxed, improving the withstand voltage of transistor TR2. Similarly, since the anode electrode 11 of diode DD1 and the SiC layer 23 are at the same potential, the electric field between the anode electrode 11 and the cathode electrode 10 is relaxed, improving the withstand voltage of diode DD1. As a result, it is possible to enhance the high withstand voltage and high output of all the devices constituting the integrated circuit.

In addition, according to this embodiment, it is possible to improve the thermal resistance of the semiconductor device ND1. Specifically, in semiconductor device ND1, heat is primarily generated inside and on the principal surface of the nitride semiconductor layer. Specifically, heat is generated inside and on the principal surfaces 41b, 42b, and 43b of the nitride semiconductor layers 41, 42, and 43 of transistors TR1 and TR2, and diode DD1, respectively. The SiC layers 21 to 23 and the diamond substrate 1 have high thermal conductivity. Therefore, this heat is efficiently released to the side of the principal surface 1b of the diamond substrate 1 via any of the SiC layers 21 to 23 and the diamond substrate 1.

In the technology of non-patent document 2, the SiC substrate is thinned by cutting the reverse side, creating a SiC layer with a thickness of 50 μm. Due to the accuracy of the cutting of the SiC substrate or in order to prevent mechanical damage to the SiC layer during processing, the lower limit of the thickness of the SiC layer is set to 50 μm. However, because the etching speed of SiC is slow, it is difficult to locally remove a 50 μm thick SiC layer by etching to form element separation (trenches 161 and 162 in this embodiment). According to the semiconductor device ND1 of this embodiment, since cutting of the SiC substrate is not required when forming the SiC layer 2, it is possible to make the SiC layer thinner than 50 μm. As a result, it is easier to form element separation.

### Third Embodiment

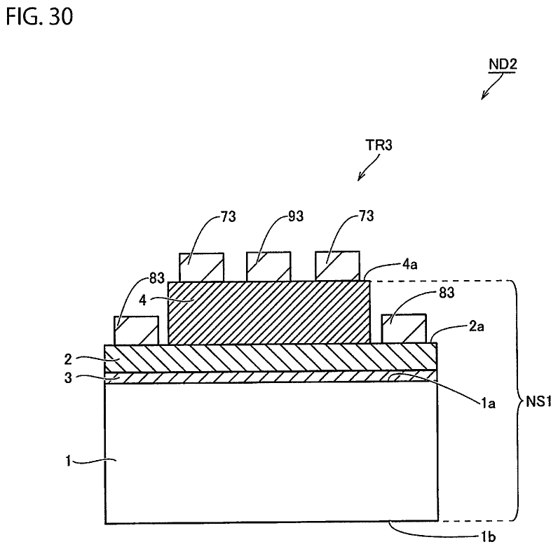

FIG. 30 is a cross-sectional diagram showing the configuration of the semiconductor device ND2 in the third embodiment of the present invention.

Referring to FIG. 30, the semiconductor device ND2 (an example of a semiconductor device) in this embodiment is manufactured using the semiconductor substrate NS1 of the first embodiment and includes the transistor TR3 as a device.

Transistor TR3 is comprising of a vertical FET (Field Effect Transistor). Transistor TR3 includes a diamond substrate 1 (an example of a thermal conduction layer), an SiC layer 2 (an example of a silicon carbide layer), a bonding layer 3 (an example of a bonding layer), a nitride semiconductor layer 4 (an example of a nitride semiconductor layer), a source electrode 73 (an example of a source electrode), a drain electrode 83 (an example of a drain electrode), and a gate electrode 93 (an example of a gate electrode). On the principal surface 1a of the diamond substrate 1, the bonding layer 3, SiC layer 2, and nitride semiconductor layer 4 are stacked in this order. On the principal surface 4a of the nitride semiconductor layer 4, the source electrode 73 and gate electrode 93 are formed. The source electrode 73, drain electrode 83, and gate electrode 93 are formed on the side of the principal surface 2a of the SiC layer 2. When viewed from the principal surface 4a side of the nitride semiconductor layer 4, the source electrode 73 surrounds the perimeter of the gate electrode 93. Also, in the area of the principal surface 2a of the SiC layer 2 where the nitride semiconductor layer 4 is not formed, the drain electrode 83 is formed. When viewed from the principal surface 4a side of the nitride semiconductor layer 4, the drain electrode 83 surrounds the perimeter of the nitride semiconductor layer 4. The drain electrode 83 is in contact with the SiC layer 2 and is electrically connected to it. The positions of the source electrode 73 and the drain electrode 83 may be exchanged.

Next, the manufacturing method of the semiconductor device ND2 will be explained.

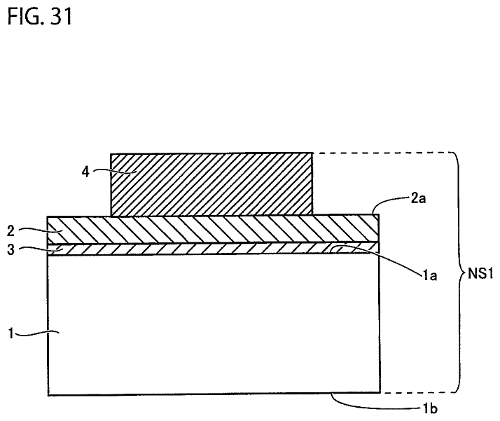

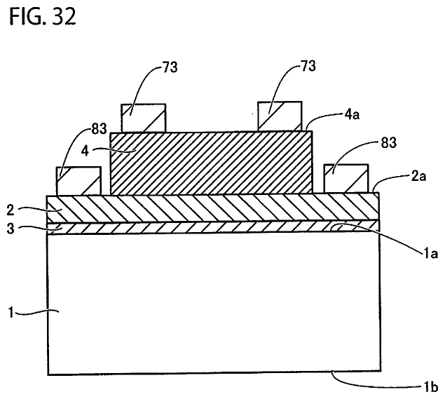

FIGS. 31 and 32 are cross-sectional diagrams showing the manufacturing method of the semiconductor device ND2 in the third embodiment of the present invention.

Referring to FIG. 31, the semiconductor substrate NS1 is prepared. Using standard photolithography and etching techniques, a predetermined area of the nitride semiconductor layer 4 is removed. The area from which the nitride semiconductor layer 4 is removed exposes the principal surface 2a of the SiC layer 2.

Referring to FIG. 32, by methods such as lift-off, the source electrode 73 is formed on the principal surface 4a of the nitride semiconductor layer 4, and the drain electrode 83 is formed on the principal surface 2a of the SiC layer 2.

Referring to FIG. 30, by methods such as lift-off, the gate electrode 93 is formed on the principal surface 4a of the nitride semiconductor layer 4. Through these processes, the semiconductor device ND2 is obtained.

Note that configurations and manufacturing methods of the semiconductor device ND2 other than those described above are the same as those for the semiconductor substrate NS1 in the first embodiment or the semiconductor device ND1 in the second embodiment, so their explanation is not repeated.

According to this embodiment, since the SiC layer 2 is conductive, it can be considered as part of the drain electrode 83. That is, according to this embodiment, it is possible to form a drain electrode directly below the drift layer, which is the nitride semiconductor layer 4. In general vertical GaN devices, directly below the drift layer, which is the nitride semiconductor layer 4, there is a substrate with parasitic resistance, and the drain electrode is formed below it. The thickness of the substrate with parasitic resistance is generally more than 50 μm, large, and when current flows through the device, a current path through this substrate with parasitic resistance is formed, causing heating in this current path and deteriorating the efficiency of the device. In semiconductor device ND2, such a current path does not exist, resulting in less parasitic resistance and the realization of a high-efficiency semiconductor device. Moreover, it is possible to improve the thermal resistance of the semiconductor device ND2. Especially in semiconductor device ND2, the drain electrode 83 and the SiC layer 2 are in direct contact. This allows for a simple method to electrically connect the drain electrode 83 of transistor TR3 and the SiC layer 2.

### Fourth Embodiment

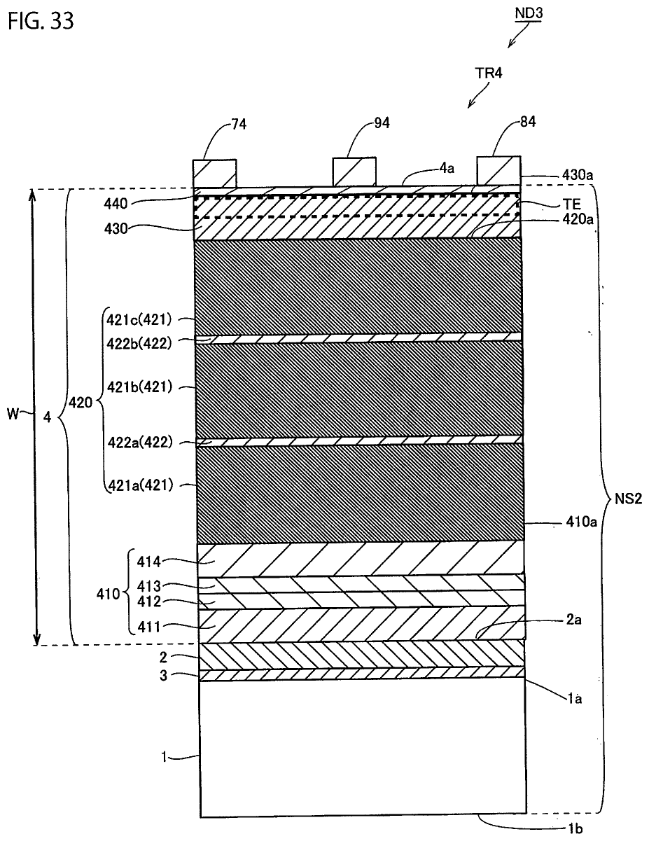

FIG. 33 is a cross-sectional diagram showing the configuration of the semiconductor device ND3 in the fourth embodiment of the present invention.

Referring to FIG. 33, the semiconductor device ND3 (an example of a semiconductor device) in this embodiment is manufactured using a semiconductor substrate NS2 (an example of a semiconductor substrate) and includes transistor TR4 as a device. Transistor TR4 consists of a HEMT and includes a diamond substrate 1 (an example of a thermal conduction layer), an SiC layer 2 (an example of a silicon carbide layer), a bonding layer 3 (an example of a bonding layer), a nitride semiconductor layer 4 (an example of a nitride semiconductor layer), a source electrode 74, a drain electrode 84, and a gate electrode 94. On the principal surface 1a of the diamond substrate 1, the bonding layer 3, SiC layer 2, and nitride semiconductor layer 4 are stacked in this order. The source electrode 74, drain electrode 84, and gate electrode 94 are formed on the principal surface 4a of the nitride semiconductor layer 4, spaced apart from each other.

The semiconductor substrate NS2 differs from the semiconductor substrate NS1 in that the composition of the nitride semiconductor layer 4 is specifically defined. The nitride semiconductor layer 4 of the semiconductor substrate NS2 includes a first nitride semiconductor layer 410 (an example of a first nitride semiconductor layer), a second nitride semiconductor layer 420 (an example of a second nitride semiconductor layer), an electron traveling layer 430 (an example of an electron traveling layer), and a barrier layer 440 (an example of a barrier layer).

The first nitride semiconductor layer 410 is formed on the principal surface 2a of the SiC layer 2. The first nitride semiconductor layer 410 consists of AlₓGa₁₋ₓN (0.1≤x≤1). It functions as a buffer layer to alleviate the lattice constant mismatch between the SiC layer 2 and the second nitride semiconductor layer 420. The first nitride semiconductor layer 410 has a thickness of, for example, 600 nm to 4 μm, preferably 1 μm to 3 μm, more preferably 1.5 μm to 2.5 μm. It is formed using Metal Organic Chemical Vapor Deposition (MOCVD). For the aluminum (Al) source gas, Trimethylaluminum (TMA) or Triethylaluminum (TEA) can be used, and for the gallium (Ga) source gas, Trimethylgallium (TMG) or Triethylgallium (TEG) can be used. Ammonia (NH3) is used as the nitrogen (N) source gas. It is preferable that the first nitride semiconductor layer 410 has a thickness less than or equal to the thickness of the second nitride semiconductor layer 420 mentioned later.

The first nitride semiconductor layer 410 is insulating or semi-insulating. However, the area of the first nitride semiconductor layer 410 close to the SiC layer 2 (the lower layer) may have extremely low crystallinity. Therefore, the area of the first nitride semiconductor layer 410 close to the SiC layer 2 does not necessarily need to be insulating or semi-insulating. In this case, the area of the first nitride semiconductor layer 410 close to the electron traveling layer 430 (the upper layer) is insulating or semi-insulating. The first nitride semiconductor layer 410 consists of an unintentionally doped layer (uid layer), a C-doped layer, or a transition metal-doped layer, etc.

A uid layer refers to a layer in which intentional introduction of impurities was not performed during the formation of the layer. A uid layer contains a slight amount of impurities unintentionally introduced during the formation of the layer (impurities in the atmosphere during layer formation).

The first nitride semiconductor layer 410 may be composed of multiple layers made of different materials as described later. The first nitride semiconductor layer 410 includes at least one of the first region consisting of AlₓGa₁₋ₓN (0.4<x≤1) and the second region with a thickness of 0.5 μm or more consisting of AlₓGa₁₋ₓN (0.1≤x≤0.4). The first nitride semiconductor layer 410 includes both the first and second regions, and it is preferable that the distance between the first region and the SiC layer 2 is smaller than the distance between the second region and the SiC layer 2.

If the first nitride semiconductor layer 410 is a uid layer, the first region of the first nitride semiconductor layer 410 has a Si concentration of 0 atoms/cm\hat{ }3 to 5×10\hat{ }17 atoms/cm\hat{ }3, an O (oxygen) concentration of 0 atoms/cm\hat{ }3 to 5×10\hat{ }17 atoms/cm\hat{ }3, and an Mg (magnesium) concentration of 0 atoms/cm\hat{ }3 to 5×10\hat{ }17 atoms/cm\hat{ }3. The second region of the first nitride semiconductor layer 410 has a Si concentration of 0 atoms/cm\hat{ }3 to 2×10\hat{ }16 atoms/cm\hat{ }3, an O concentration of 0 atoms/cm\hat{ }3 to 2×10\hat{ }16 atoms/cm\hat{ }3, and an Mg concentration of 0 atoms/cm\hat{ }3 to 2×10\hat{ }16 atoms/cm\hat{ }3. Furthermore, at least one of the C concentration or Fe (iron) concentration in the second region of the first nitride semiconductor layer 410 is higher than any of the Si concentration, O concentration, and Mg concentration in the second region of the first nitride semiconductor layer 410, and less than or equal to 5×10\hat{ }19 atoms/cm\hat{ }3. This improves the insulating properties of the first nitride semiconductor layer.

The second nitride semiconductor layer 420 is formed on the principal surface 410a of the first nitride semiconductor layer 410. The second nitride semiconductor layer 420 is formed between the first nitride semiconductor layer 410 and the electron traveling layer 430. It is preferable that C or Fe is intentionally introduced into the second nitride semiconductor layer 420. In this case, at least one of the C concentration or Fe concentration in the second nitride semiconductor layer 420 is preferably higher than any of the Si concentration, O concentration, and Mg concentration in the second nitride semiconductor layer 420, and less than or equal to 5×10\hat{ }19 atoms/cm\hat{ }3. The second nitride semiconductor layer 420 includes a C—GaN layer 421 (an example of a main layer) and an intermediate layer 422 (an example of an intermediate layer).

A C—GaN layer 421 is a GaN layer containing C (a GaN layer into which C has been intentionally introduced). C plays a role in enhancing the insulating properties of GaN. The C—GaN layer 421 does not have any intentional introduction of impurities other than C during the formation of the layer. In this case, the C—GaN layer 421 has a Si concentration of 0 atoms/cm\hat{ }3 to 2×10\hat{ }16 atoms/cm\hat{ }3, an O concentration of 0 atoms/cm\hat{ }3 to 2×10\hat{ }16 atoms/cm\hat{ }3, and an Mg concentration of 0 atoms/cm\hat{ }3 to 2×10\hat{ }16 atoms/cm\hat{ }3. Also, the C—GaN layer 421 includes a region where the concentration of activated donor ions is 0 atoms/cm\hat{ }3 to 2×10\hat{ }14 atoms/cm\hat{ }3.

The main layer constituting the second nitride semiconductor layer 420 is not limited to the C—GaN layer 421 but may consist of insulating or semi-insulating Al_{y}Ga_{1-y}N (0≤y<0.1). The main layer constituting the second nitride semiconductor layer 420 preferably has a C concentration higher than the C concentration of the electron traveling layer 430 and an Fe concentration higher than the Fe concentration of the electron traveling layer 430, at least one of which. On the other hand, it is preferable that no intentional introduction of impurities other than the aforementioned C and Fe was performed during the formation of the main layer constituting the second nitride semiconductor layer 420.

The intermediate layer 422 is formed on at least one of the inside and on top of the C—GaN layer 421. The intermediate layer 422 consists of Al_{y}Ga_{1-y}N (0.5≤ y≤1). Preferably, the intermediate layer 422 consists of AlN. The intermediate layer 422 may be one or more layers. Preferably, the intermediate layer 422 is two layers or less, more preferably one layer. Additionally, the intermediate layer 422 may be the topmost layer constituting the second nitride semiconductor layer 420, and it may contact the electron traveling layer 430.

The second nitride semiconductor layer 420 includes two intermediate layers 422a and 422b. The intermediate layers 422a and 422b are formed inside the C—GaN layer 421. By the intermediate layers 422a and 422b, the C—GaN layer 421 is divided into three C—GaN layers 421a, 421b, and 421c. The C—GaN layer 421a is the bottommost layer constituting the second nitride semiconductor layer 420 and contacts the first nitride semiconductor layer 410. The intermediate layer 422a contacts the C—GaN layer 421a and is formed on top of the C—GaN layer 421a. The C—GaN layer 421b contacts the intermediate layer 422a and is formed on top of the intermediate layer 422a. The intermediate layer 422b contacts the C—GaN layer 421b and is formed on top of the C—GaN layer 421b. The C—GaN layer 421c contacts the intermediate layer 422b and is formed on top of the intermediate layer 422b. The C—GaN layer 421c is the topmost layer constituting the second nitride semiconductor layer 420 and contacts the electron traveling layer 430.

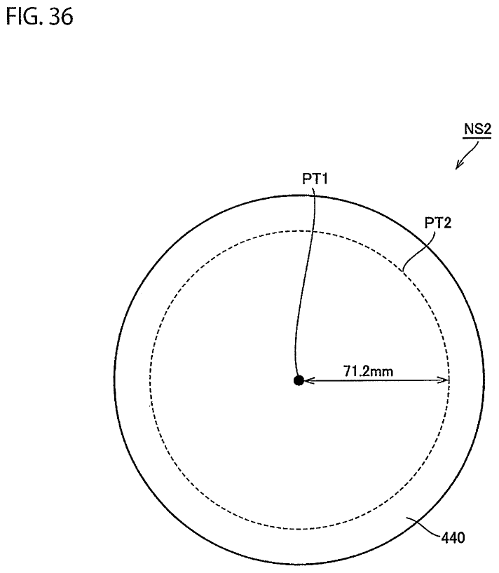

The average carbon concentration in the depth direction at the center PT1 (see FIG. 36) of the C—GaN layer 421 (in this embodiment, each of the C—GaN layers 421a, 421b, and 421c) is between 3×10\hat{ }18 atoms/cm\hat{ }3 and 5×10\hat{ }20 atoms/cm\hat{ }3, preferably between 3×10\hat{ }18 atoms/cm\hat{ }3 and 2×10\hat{ }19 atoms/cm\hat{ }3. If the C—GaN layer 421 is divided into multiple C—GaN layers, each of the multiple C—GaN layers may have the same average carbon concentration or different average carbon concentrations. It is preferable that the topmost C—GaN layer among the multiple C—GaN layers has a C concentration higher than the C concentration of the electron traveling layer 430.

Additionally, if the C—GaN layer 421 is divided into multiple C—GaN layers, each of the multiple C—GaN layers, for example, has a thickness between 550 nm and 3000 nm, preferably between 800 nm and 2500 nm. Each of the multiple C—GaN layers may have the same thickness or different thicknesses.

If the second nitride semiconductor layer 420 includes two or more intermediate layers 422 (in this embodiment, intermediate layers 422a and 422b), each of the two or more intermediate layers may have the same thickness or different thicknesses. Each of the two or more intermediate layers preferably has a thickness between 10 nm and 30 nm. Each of the two or more intermediate layers is formed at intervals between 0.5 μm and 10 μm.

The second nitride semiconductor layer 420 is formed using the MOCVD method. Generally, when forming a C—GaN layer, the growth temperature of the GaN layer is set lower than the growth temperature of the GaN layer does not incorporate C (specifically, about 300° C. lower than the growth temperature for GaN layers without intentional doping of C). This allows C contained in the Ga source gas to be incorporated into the GaN layer, turning it into a C—GaN layer. However, as the growth temperature of the GaN layer decreases, the quality of the C—GaN layer deteriorates, and the uniformity of the C concentration within the C—GaN layer decreases.

Therefore, the inventors of the present application found a method of introducing a hydrocarbon as a C source gas (C precursor) along with Ga source gas and N source gas into the reaction chamber when forming a C—GaN layer. According to this method, the incorporation of C into the GaN layer is promoted, allowing the formation of a C—GaN layer while setting the growth temperature of GaN higher (specifically, about 200° C. lower than the growth temperature for GaN layers without intentional doping of C). As a result, the quality of the C—GaN layer improves, and the uniformity of the C concentration within the C—GaN layer improves.

Specifically, as the C source gas, hydrocarbons such as methane, ethane, propane, butane, pentane, hexane, heptane, octane, ethylene, propylene, butene, pentene, hexene, heptene, octene, acetylene, propyne, butyne, pentyne, hexyne, heptyne, or octyne can be used. Particularly, hydrocarbons containing double or triple bonds are preferred due to their high reactivity. One type of hydrocarbon may be used as the C source gas, or two or more types of hydrocarbons may be used.

Additionally, it is preferable that the first nitride semiconductor layer 410 has a thickness less than or equal to the thickness of the second nitride semiconductor layer 420. When forming an Al-containing nitride layer using MOCVD, organic metal gas containing Al and source gas containing ammonia are introduced onto the substrate. If the flow rate of the source gas is high, unnecessary reactions between the organic metal gas containing Al and ammonia occur, generating particles in the gas phase. Therefore, it is not possible to increase the flow rate of the source gas, and a long time is required to form an Al-containing nitride layer. The Al composition ratio of the first nitride semiconductor layer 410 is higher than the Al composition ratio of the main layer of the second nitride semiconductor layer 420. Therefore, having the first nitride semiconductor layer 410 with a thickness less than or equal to the thickness of the second nitride semiconductor layer 420 allows for a reduction in the time required to form the first and second nitride semiconductor layers.

Note that other layers such as a uid layer as a GaN layer (uid-GaN layer) may be interposed between the first nitride semiconductor layer 410 and the second nitride semiconductor layer 420. The second nitride semiconductor layer 420 may include layers other than the intermediate layer, or the intermediate layer may be omitted.

The electron traveling layer 430 contacts the second nitride semiconductor layer 420 and is formed on the principal surface 420a of the second nitride semiconductor layer 420. The electron traveling layer 430 consists of Al_{z}Ga_{1-z}N (0≤z<0.1). It is preferable that the electron traveling layer 430 is a uid layer, meaning that no intentional introduction of impurities for n-doping, p-doping, or semi-insulating was performed during its formation. In this case, the Si concentration, O concentration, Mg concentration, C concentration, and Fe (iron) concentration of the electron traveling layer 430 are all greater than 0 and less than or equal to 1×10\hat{ }17 atoms/cm\hat{ }3. It is more preferable that the electron traveling layer 430 has a Si concentration of 0 atoms/cm\hat{ }3 to 1×10\hat{ }16 atoms/cm\hat{ }3, an O concentration of 0 atoms/cm\hat{ }3 to 1×10\hat{ }16 atoms/cm\hat{ }3, an Mg concentration of 0 atoms/cm\hat{ }3 to 1×10\hat{ }16 atoms/cm\hat{ }3, a C concentration of 0 atoms/cm\hat{ }3 to 1×10\hat{ }17 atoms/cm\hat{ }3, and an Fe concentration of 0 atoms/cm\hat{ }3 to 1×10\hat{ }17 atoms/cm\hat{ }3. The electron traveling layer 430, for example, has a thickness of 0.3 μm to 5 μm. The electron traveling layer 430 is formed using the MOCVD method.

Especially, the region of the electron traveling layer 430 within 0.5 μm from the boundary with the barrier layer 440 preferably has a C concentration of 0 or more and less than or equal to 1×10\hat{ }17 atoms/cm\hat{ }3. If the region of the electron traveling layer 430 within 0.5 μm from the boundary with the barrier layer 440 has the aforementioned C concentration, the region of the electron traveling layer 430 within 3 μm from the boundary with the barrier layer 440 preferably has a C concentration of 0 or more and less than or equal to 1×10\hat{ }18 atoms/cm\hat{ }3. Setting the C concentration in the region near the two-dimensional electron gas TE within the above range can suppress current collapse, preventing deterioration of the high-frequency characteristics of the HEMT.

The barrier layer 440 is formed on the principal surface 430a of the electron traveling layer 430. The barrier layer 440 consists of a nitride semiconductor with a wider bandgap than the bandgap of the electron traveling layer 430. For example, the barrier layer 440 consists of an Al-containing nitride semiconductor, represented by the material AlₐGa₁₋ₐN (0<a≤1). Preferably, the barrier layer 440 consists of AlₐGa₁₋ₐN (0.17≤a≤0.27), more preferably AlₐGa₁₋ₐN (0.19≤a≤0.22). The barrier layer 440, for example, has a thickness of 10 nm to 50 nm, preferably 25 nm to 34 nm. When the barrier layer 440 consists of a material represented by AlₐGa₁₋ₐN (0<a≤1), the growth temperature during the formation of the barrier layer 440 is, for example, between 1000° C. and 1100° C. The barrier layer 440 is formed using the MOCVD method.

Note that a spacer layer or other layers may be interposed between the electron traveling layer 430 and the barrier layer 440. A cap layer or passivation layer may be formed on the barrier layer 440. The source electrode 74 or drain electrode 84 may be electrically connected to the SiC layer 2 through a conductive layer. This conductive layer may be formed inside a hole (via hole) reaching from the principal surface 4a of the nitride semiconductor layer 4 to the principal surface 2a of the SiC layer 2.

The semiconductor device ND3 is manufactured as follows. A semiconductor substrate NS2 is manufactured in almost the same manner as the semiconductor substrate NS1 described in the first embodiment. However, when forming the nitride semiconductor layer 4 on the principal surface 2a of the SiC layer 2, the first nitride semiconductor layer 410, the second nitride semiconductor layer 420, the electron traveling layer 430, and the barrier layer 440 are stacked in this order on the principal surface 2a of the SiC layer 2. The source electrode 74 and drain electrode 84 are formed on the principal surface 4a of the nitride semiconductor layer 4 in the semiconductor substrate NS2 obtained. The gate electrode 94 is formed on the principal surface 4a of the nitride semiconductor layer 4. Through these processes, the semiconductor device ND3 is obtained.

The Si substrate 90 (see FIG. 2) used when manufacturing the semiconductor substrate is preferably made using the Czochralski (Cz) method. In the Cz method, a seed crystal of Si is gradually pulled up from molten Si in a quartz crucible under a specified atmosphere such as Ar. Si adhering to the seed crystal is cooled in the atmosphere and crystallizes, resulting in a single crystal of Si. In the Cz method, as Si crystallizes, oxygen contained in the quartz material of the crucible is incorporated into the crystal. Therefore, compared to an Si substrate made using the Fz method, the Si substrate 90 has a higher oxygen concentration. Specifically, the Si substrate 90 has an oxygen concentration of 3×10\hat{ }17 atoms/cm\hat{ }3 to 3×10\hat{ }18 atoms/cm\hat{ }3. Because the Si substrate 90 has a high oxygen concentration, it has a higher elastic limit compared to an Si substrate made using the Fz (Float zone) method. The Si substrate 90 is easier to obtain in large sizes (e.g., a diameter of 8 inches) and is less expensive compared to an SiC substrate or others.

Preferably, the Si substrate 90 is made of p+ type Si. The Si substrate 90 does not necessarily need to be intentionally doped. The upper surface of the Si substrate 90 exposes the (111) plane. The upper surface of the Si substrate 90 has an off-angle of 0 to 1 degree, more preferably 0.5 degrees or less. The Si substrate 90 preferably has a single-crystal diamond structure.

If the Si substrate 90 contains boron (B) and has a p type conductivity, for example, it has a resistivity of 0.1 mΩcm to 100 mΩcm. It is preferable that the Si substrate 90 has a resistivity of 0.5 mΩcm to 20 mΩcm, more preferably 1 mΩcm to 5 mΩcm.

Preferably, the Si substrate 90 has a diameter of about 50 mm (for example, 47 mm to 53 mm) and a thickness of 270 μm to 1600 μm. The Si substrate 90 has a diameter of about 50.8 mm (for example, 47.8 mm to 53.8 mm) and a thickness of 270 μm to 1600 μm. The Si substrate 90 has a diameter of about 75 mm (for example, 72 mm to 78 mm) and a thickness of 350 μm to 1600 μm. The Si substrate 90 has a diameter of about 76.2 mm (for example, 73.2 mm to 79.2 mm) and a thickness of 350 μm to 1600 μm. The Si substrate 90 has a diameter of about 100 mm (for example, 97 mm to 103 mm) and a thickness of 500 μm to 1600 μm. The Si substrate 90 has a diameter of about 125 mm (for example, 122 mm to 128 mm) and a thickness of 600 μm to 1600 μm. The Si substrate 90 has a diameter of about 150 mm (for example, 147 mm to 153 mm) and a thickness of 600 μm to 1600 μm. Or, the Si substrate 90 has a diameter of about 200 mm (for example, 197 mm to 203 mm) and a thickness of 700 μm to 2100 μm.

More preferably, the Si substrate 90 has a diameter of about 100 mm (for example, 99.5 mm to 100.5 mm) and a thickness of 700 μm to 1100 μm. The Si substrate 90 has a diameter of about 125 mm (for example, 124.5 mm to 125.5 mm) and a thickness of 700 μm to 1100 μm. The Si substrate 90 has a diameter of about 150 mm (for example, 149.8 mm to 150.2 mm) and a thickness of 900 μm to 1100 μm. Or, the Si substrate 90 has a diameter of about 200 mm (for example, 199.8 mm to 200.2 mm) and a thickness of 900 μm to 1600 μm.

Note that the Si substrate 90 may also have an n type conductivity. The upper surface of the Si substrate 90 may expose the (100) or (110) plane.

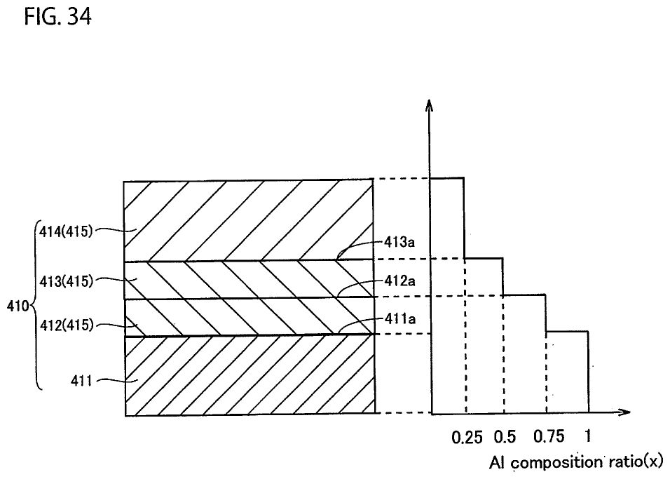

FIG. 34 shows the distribution of the Al composition ratio inside the first nitride semiconductor layer 410 in the fourth embodiment of the present invention.

Referring to FIG. 34, the Al composition ratio inside the first nitride semiconductor layer 410 decreases from the bottom to the top. The first nitride semiconductor layer 410 includes an AlN layer 411 and an AlGaN layer 415. The AlN layer 411 is formed on the principal surface 2a of the SiC layer 2.

The AlGaN layer 415 is formed on the principal surface 411a of the AlN layer 411. The Al composition ratio inside the AlGaN layer 415 decreases from the bottom to the top. The AlGaN layer 415 is composed of an Al_{0.75}Ga_{0.25}N layer 412 (an AlGaN layer with an Al composition ratio of 0.75), an Al_{0.5}Ga_{0.5}N layer 413 (an AlGaN layer with an Al composition ratio of 0.5), and an Al_{0.25}Ga_{0.75}N layer 414 (an AlGaN layer with an Al composition ratio of 0.25). The Al_{0.75}Ga_{0.25}N layer 412 is formed on the principal surface 411a of the AlN layer 411. The Al_{0.5}Ga_{0.5}N layer 413 is formed on the principal surface 412a of the Al_{0.75}Ga_{0.25}N layer 412. The Al_{0.25}Ga_{0.75}N layer 414 is formed on the principal surface 413a of the Al_{0.5}Ga_{0.5}N layer 413.

Each of the AlN layer 411, Al_{0.75}Ga_{0.25}N layer 412, and Al_{0.5}Ga_{0.5}N layer 413 corresponds to the first region of the first nitride semiconductor layer 410 consisting of AlₓGa₁₋ₓN (0.4<x≤1). The Al_{0.25}Ga_{0.75}N layer 414 corresponds to the second region of the first nitride semiconductor layer 410 consisting of AlₓGa₁₋ₓN (0.1≤x≤0.4).

Note that the Al composition ratio inside the first nitride semiconductor layer 410 is arbitrary. If the first nitride semiconductor layer 410 is composed of multiple layers, the bottommost layer being an AlN layer is preferred.

Referring to FIG. 33, the total thickness W of the nitride semiconductor layer 4 is preferably between 6 μm and 10 μm. A thickness W of 7.5 μm to 8.5 μm is more preferable. With a thickness W of 6 μm or more, the direction from the two-dimensional electron gas TE towards the substrate side is thickly covered with insulating or semi-insulating layers. As a result, it is possible to suppress high-frequency loss due to the parasitic capacitance and parasitic resistance of the substrate, improving the high-frequency characteristics of the HEMT. Also, with a thickness W of 10 μm or less, it is possible to suppress the occurrence of cracks and warping of the substrate due to the increased total thickness W of the nitride semiconductor layer 4. Specifically, the amount of warping of the semiconductor substrate NS2 can be kept within a range greater than 0 and less than or equal to 50 μm. When the total thickness W of the nitride semiconductor layer 4 is between 6 μm and 10 μm, the diamond substrate 1 and the SiC layer 2 may be conductive, semi-insulating, or insulating.

Also, if the total thickness W of the nitride semiconductor layer 4 is 0.5 μm or more and less than 6 μm, each of the diamond substrate 1 and the SiC layer 2 is preferably a semi-insulating substrate or an insulating substrate. Specifically, the diamond substrate 1 preferably has a resistivity between 5×10\hat{ }3 Ω·cm and 1×10\hat{ }16 Ω·cm. The SiC layer 2 preferably has a resistivity between 1×10\hat{ }3 Ω·cm and 1×10\hat{ }16 Ω·cm. In this case, too, the direction from the two-dimensional electron gas TE towards the substrate side is thickly covered with insulating or semi-insulating layers. As a result, it is possible to suppress high-frequency loss due to the parasitic capacitance and parasitic resistance of the substrate, improving the high-frequency characteristics of the HEMT.

In the first embodiment, preferred first to third configurations for the semiconductor substrate NS1 were described. The configuration of the semiconductor device ND3 with a total thickness W of the nitride semiconductor layer 4 between 6 μm and 10 μm corresponds to the second configuration described above. The configuration of the semiconductor device ND3 with a total thickness W of the nitride semiconductor layer 4 between 0.5 μm and less than 6 μm, and both the diamond substrate 1 and the SiC layer 2 being either a semi-insulating substrate or an insulating substrate, corresponds to the third configuration described above.

Also, the Si substrate 90 is made using the Cz method. Therefore, the Si substrate 90 has a high oxygen concentration of between 5×10\hat{ }17 atoms/cm\hat{ }3 and 1×10\hat{ }19 atoms/cm\hat{ }3, and has a high elastic limit. Using the Si substrate 90 made by the Cz method, it is possible to suppress warping of the substrate caused by the first nitride semiconductor layer 410, the second nitride semiconductor layer 420, and the electron traveling layer 430 with a total thickness W of between 6 μm and 10 μm. Also, by forming the SiC layer 2 between the Si substrate 90 and the first nitride semiconductor layer 410, it is possible to suppress meltback etching caused by the reaction between Ga contained in the layers formed on the Si substrate 90 and the Si of the Si substrate 90. Additionally, by forming the SiC layer 2 between the Si substrate 90 and the first nitride semiconductor layer 410, the SiC layer 2 acts as a buffer layer between the Si substrate 90 and the first nitride semiconductor layer 410, suppressing the occurrence of cracks in the first nitride semiconductor layer 410. As a result, it is possible to provide semiconductor substrates and semiconductor devices of high quality.

Moreover, according to this embodiment, by forming the intermediate layer 422 on at least one of the inside and on top of the C—GaN layer 421 in the second nitride semiconductor layer 420, it is possible to suppress the occurrence of warping of the Si substrate 90 and cracks in the C—GaN layer 421 or the electron traveling layer 430 on top of the intermediate layer 422. This will be explained below.

When the intermediate layer 422 is formed inside the C—GaN layer 421, the substrate for the intermediate layer 422 is the C—GaN layer 421, and the layer formed on top of the intermediate layer 422 is also the C—GaN layer 421. When the intermediate layer 422 is formed on top of the C—GaN layer 421, the substrate for the intermediate layer 422 is the C—GaN layer 421, and the layer formed on top of the intermediate layer 422 is the electron traveling layer 430.

The Al_{y}Ga_{1-y}N (0.5≤y≤1) constituting the intermediate layer 422 epitaxially grows on the C—GaN layer 421, which constitutes the substrate, in a mismatched state (with slip) with respect to the crystal of GaN (generally, the main layer constituting Al_{y}Ga_{1-y}N(0≤y<0.1)) constituting the C—GaN layer 421. On the other hand, the GaN constituting the C—GaN layer 421 on top of the intermediate layer 422 or Al_{z}Ga_{1-z}N (0≤z<0.1) constituting the electron traveling layer 430 is affected by the crystal of the intermediate layer 422 constituting Al_{y}Ga_{1-y}N(0.5≤y≤1). That is, GaN constituting the C—GaN layer 421 or Al_{z}Ga_{1-z}N (0≤z<0.1) constituting the electron traveling layer 430 epitaxially grows on the intermediate layer 422, inheriting the crystal structure of the intermediate layer 422 constituting Al_{y}Ga_{1-y}N (0.5≤y≤1). Since the lattice constants of GaN and Al_{z}Ga_{1-z}N (0≤z<0.1) are larger than the lattice constant of Al_{y}Ga_{1-y}N(0.5≤y≤1), the lateral lattice constants of GaN and Al_{z}Ga_{1-z}N (0≤z<0.1) on top of the intermediate layer 422 are smaller than the general lattice constants of GaN and Al_{z}Ga_{1-z}N (0≤z<0.1) (that do not include compressive strain). In other words, the C—GaN layer 421 or the electron traveling layer 430 on top of the intermediate layer 422 includes compressive strain inside.

When cooling after forming the C—GaN layer 421 and the electron traveling layer 430, the difference in thermal expansion coefficients between GaN or Al_{z}Ga_{1-z}N (0≤z<0.1) and Si causes stress from the intermediate layer 422, which is the substrate, to the C—GaN layer 421 and the electron traveling layer 430. This stress could cause warping of the Si substrate 90 and the occurrence of cracks in the C—GaN layer 421 and the electron traveling layer 430. However, this stress is alleviated by the compressive strain introduced into the C—GaN layer 421 or the electron traveling layer 430 on top of the intermediate layer 422 during their formation. As a result, it is possible to suppress the occurrence of warping of the Si substrate 90 and cracks in the C—GaN layer 421 or the electron traveling layer 430.

Moreover, the semiconductor device ND3 includes the C—GaN layer 421, the intermediate layer 422, and the first nitride semiconductor layer 410, which have a higher insulation breakdown voltage than that of GaN. As a result, it is possible to improve the vertical breakdown voltage of the semiconductor device ND3.

Additionally, according to this embodiment, because the first nitride semiconductor layer 410 is included between the Si substrate 90 and the electron traveling layer 430, it is possible to alleviate the difference between the lattice constant of Si and the lattice constant of Al_{z}Ga_{1-z}N (0≤z<0.1) of the electron traveling layer 430. This is because the lattice constant of AlₓGa₁₋ₓN (0.1≤x≤1) of the first nitride semiconductor layer 410 is between the lattice constant of Si and the lattice constant of Al_{z}Ga_{1-z}N (0≤z<0.1). As a result, it is possible to improve the crystal quality of the electron traveling layer 430. Also, it is possible to suppress the occurrence of warping of the Si substrate 90 and cracks in the C—GaN layer 421 and the electron traveling layer 430.

Additionally, according to this embodiment, since the occurrence of warping of the Si substrate 90 and cracks in the electron traveling layer 430 are suppressed, it is possible to thicken the electron traveling layer 430.

Furthermore, the semiconductor device ND3 includes the SiC layer 2 as the underlying layer of the electron traveling layer 430. The lattice constant of SiC is closer to the lattice constant of Al_{z}Ga_{1-z}N (0≤z<0.1) of the electron traveling layer 430 compared to the lattice constant of Si. By forming the C—GaN layer 421 and the electron traveling layer 430 on the SiC layer 2, it is possible to improve the crystal quality of the C—GaN layer 421 and the electron traveling layer 430.

As described above, according to this embodiment, by separating the functions of the first nitride semiconductor layer 410, the second nitride semiconductor layer 420, and the SiC layer 2, it is possible to enhance the effect of suppressing the occurrence of warping of the Si substrate 90, the effect of suppressing the occurrence of cracks in the C—GaN layer 421 and the electron traveling layer 430, the effect of improving the breakdown voltage of the semiconductor device ND3, and the effect of improving the crystal quality of the C—GaN layer 421 and the electron traveling layer 430. Particularly, in this embodiment, the contribution of improving the crystal quality of the electron traveling layer 430 by using the SiC layer 2 as the underlying layer is significant.

According to this embodiment, there is a SiC layer 2, and the crystal quality of the C—GaN layer 421 and the electron traveling layer 430 improves, which allows for more efficient suppression of warping and crack occurrence by the intermediate layer 422 in the second nitride semiconductor layer 420. Also, because there is a SiC layer 2, and the crystal quality of the C—GaN layer 421 improves, it is possible to thicken the C—GaN layer 421 and the electron traveling layer 430, thereby improving the breakdown voltage. The performance of the HEMT can also be improved.

In this embodiment, the second nitride semiconductor layer 420 includes one or more intermediate layers 422 formed on at least one of the inside and on top of the C—GaN layer 421, comprising Al_{y}Ga_{1-y}N(0.5≤y≤1) intermediate layer 422. The C—GaN layer 421 has a higher C concentration and a higher Fe concentration than the electron traveling layer 430, at least one of which. This allows for enhanced insulation of the nitride semiconductor layer while suppressing the occurrence of warping and cracks.

According to this embodiment, it is possible to control the warping amount to 0 or more and 50 μm or less in a semiconductor substrate NS2 (a large-diameter semiconductor substrate) with a diameter of 100 mm or more and 200 mm or less. Additionally, it is possible to ensure that areas other than those within 5 mm from the outer edge on the upper surface of the semiconductor substrate NS2 do not contain cracks. Furthermore, it is possible to ensure that the upper surface of the semiconductor substrate NS2 does not contain traces of meltback etching.

Additionally, by introducing hydrocarbons as the C source gas when forming the C—GaN layer 421, it is possible to form the C—GaN layer 421 while setting the growth temperature of GaN higher. Since the growth temperature of GaN is higher, the quality of the C—GaN layer 421 improves.

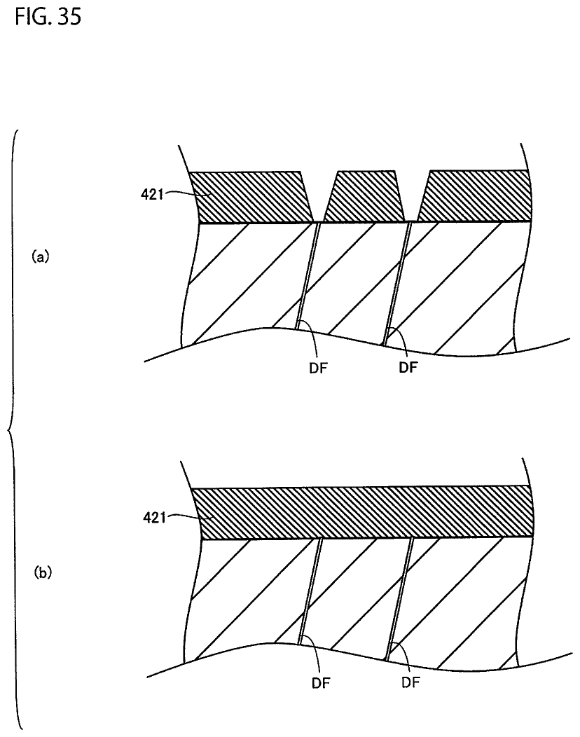

FIG. 35 is a schematic diagram showing the two-dimensional growth of GaN constituting the C—GaN layer 421. FIG. 35(a) shows the growth of GaN at a low temperature, and FIG. 36(b) shows the growth of GaN at a high temperature.

Referring to FIG. 35(a), at a low growth temperature of GaN, the two-dimensional growth (lateral direction in FIG. 35) of the C—GaN layer 421 is slow, so defects DF such as pits existing in the lower layer of the C—GaN layer 421 are not covered by the C—GaN layer 421, making it easy for the defects DF to spread inside the C—GaN layer 421.

Referring to FIG. 35(b), in this embodiment, since the growth temperature of GaN is high, the two-dimensional growth of GaN is promoted, and defects DF such as pits existing in the lower layer of the C—GaN layer 421 are covered by the C—GaN layer 421. As a result, it is possible to reduce the defect density of the C—GaN layer 421, avoiding the situation where defects DF penetrate the semiconductor substrate vertically, significantly reducing the breakdown voltage of the semiconductor substrate.

FIG. 36 is a plan view showing the configuration of the semiconductor substrate NS2 in the fourth embodiment of the present invention.

Referring to FIG. 36, the planar shape of the semiconductor substrate NS2 is arbitrary. If the semiconductor substrate NS2 has a circular planar shape, its diameter is 6 inches or more. When viewed planarly, the center of the semiconductor substrate NS2 is the center PT1, and the position 71.2 mm away from the center PT1 (corresponding to a position 5 mm away from the outer edge in a 6-inch substrate) is the edge PT2.

As a result of the improved quality of the C—GaN layer 421, the in-plane uniformity of the film thickness of the C—GaN layer 421 improves, and the in-plane uniformity of the C concentration of the C—GaN layer 421 improves. Additionally, the intrinsic breakdown voltage value in the vertical direction of the semiconductor substrate NS2 improves, and the defect density of the C—GaN layer 421 decreases. As a result, it is possible to improve the in-plane uniformity of the current-voltage characteristics.

Specifically, if the carbon concentration at the center position in the depth direction (vertical direction in FIG. 34) at the center PT1 of the C—GaN layer 421 is concentration C1, and the carbon concentration at the center position in the depth direction at the edge PT2 of the C—GaN layer 421 is concentration C2, then the concentration error ΔC (%)=|C1-C2|×100/C1 is 0 or more and 50% or less, preferably 0 or more and 33% or less.

Additionally, if the film thickness at the center PT1 of the C—GaN layer 421 is film thickness W1, and the film thickness at the edge PT2 of the C—GaN layer 421 is film thickness W2,
then the film thickness error ΔW (%)=|W1-W2|×100/W1 is greater than 0 and 8% or less, preferably greater than 0 and 4% or less.

### [Modification Examples of Manufacturing Methods for the Second to Fourth Embodiments]

The semiconductor devices ND1, ND2, and ND3 in the second to fourth embodiments may be manufactured by removing the silicon substrate 91 after forming the device (specifically, transistor TR1, TR2, TR3, or TR4, or diode DD1) and then bonding the diamond substrate 1 with the SiC layer 2, instead of the aforementioned manufacturing method. An example of such a manufacturing method is described below for the modified manufacturing method of the semiconductor device ND3 in the fourth embodiment shown in FIG. 33.

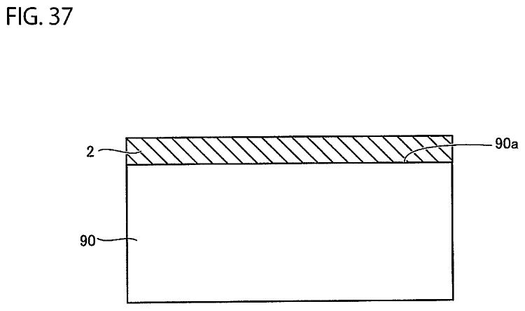

FIGS. 37 to 41 are cross-sectional views showing a modified example of the manufacturing method for the semiconductor device ND3 in the fourth embodiment of the present invention.

Referring to FIG. 37, the Si substrate 90 is prepared. On the principal surface 90a of the Si substrate 90, an SiC layer 2 having a 3C crystal structure is formed.

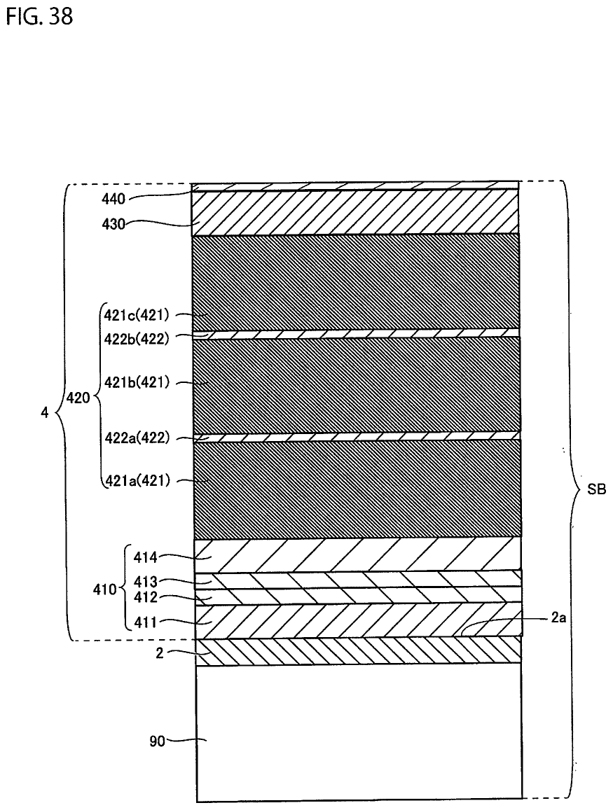

Referring to FIG. 38, the nitride semiconductor layer 4 is formed on the principal surface 2a of the SiC layer 2, thereby creating a semiconductor substrate SB.

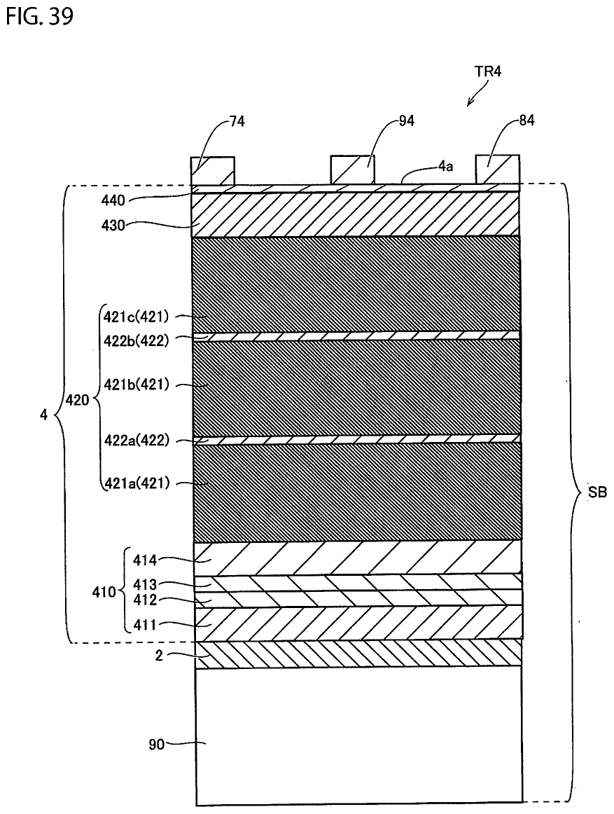

Referring to FIG. 39, manufacture the device on the semiconductor substrate SB. Here, a transistor TR4, which is a device included in the semiconductor device ND3, is manufactured by forming source electrode 74, drain electrode 84, and gate electrode 94 on the principal surface 4a of the nitride semiconductor layer 4.

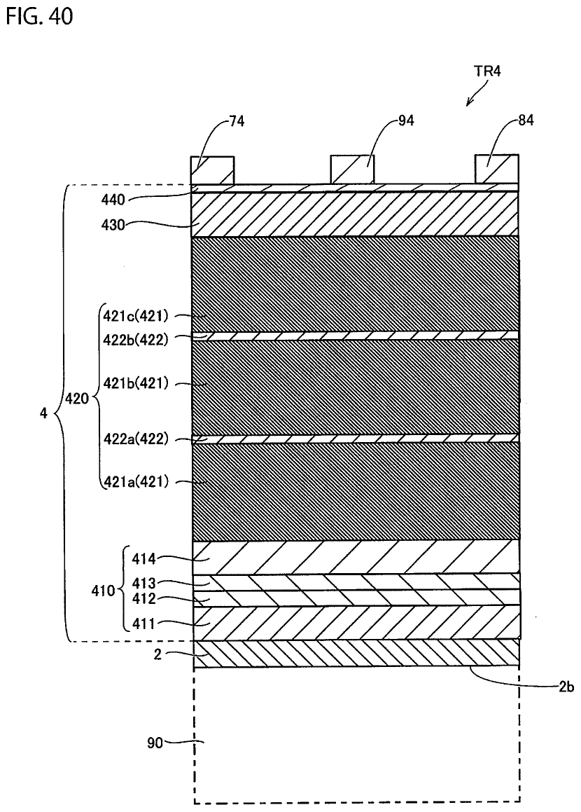

Referring to FIG. 40, after manufacturing the device, selectively etch the Si substrate 90 to remove the entire Si substrate 90 (in FIG. 35, the removed Si substrate 90 is shown with a dotted line). After the removal of the Si substrate 90, the principal surface 2b of the SiC layer 2 is exposed.

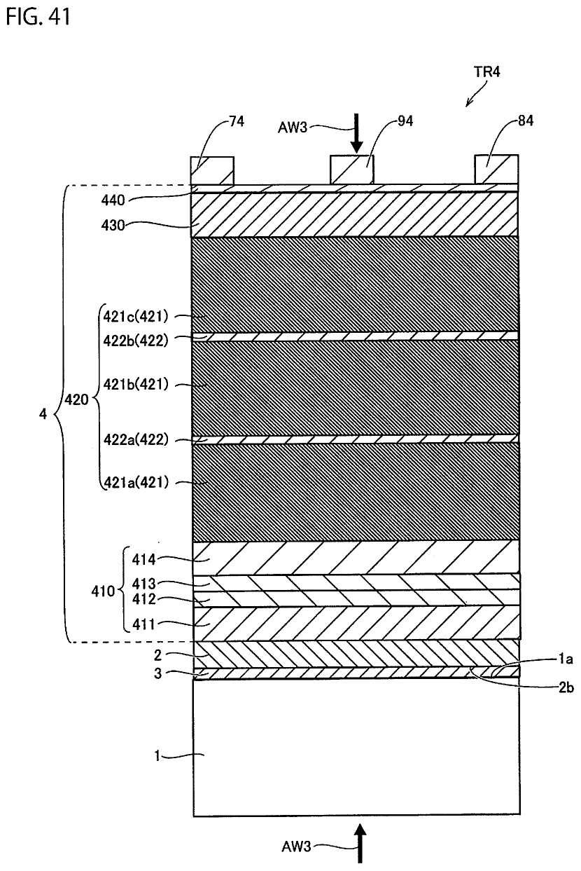

Referring to FIGS. 41 and 33, after exposing the principal surface 2b of the SiC layer 2, bond the principal surface 2b of the SiC layer 2 with the principal surface 1a of the diamond substrate 1, as indicated by arrow AW3. By bonding, a bonding layer 3 is formed between the principal surface 1a of the diamond substrate 1 and the principal surface 2b of the SiC layer 2, thereby obtaining the semiconductor device ND3.

Note, the manufacturing methods other than those described in this modification example are similar to the manufacturing method for the semiconductor device ND3 in the third embodiment, so their description is not repeated.

In the above embodiments and modification examples, the thermal conduction layer may be made of polycrystalline SiC (poly SiC) instead of diamond. Polycrystalline SiC has a high thermal conductivity similar to diamond. Therefore, when the thermal conduction layer is made of polycrystalline SiC, it can improve the thermal resistance of the semiconductor device, just like when the thermal conduction layer is made of diamond.

### EXAMPLES

As a first example, the inventors conducted the following simulation to confirm the effects of the present application.

The inventors manufactured samples 1 to 5, each having a structure ST1 or ST2, and calculated the relationship between the gate-drain distance LDG and the breakdown voltage for each of samples 1 to 5.

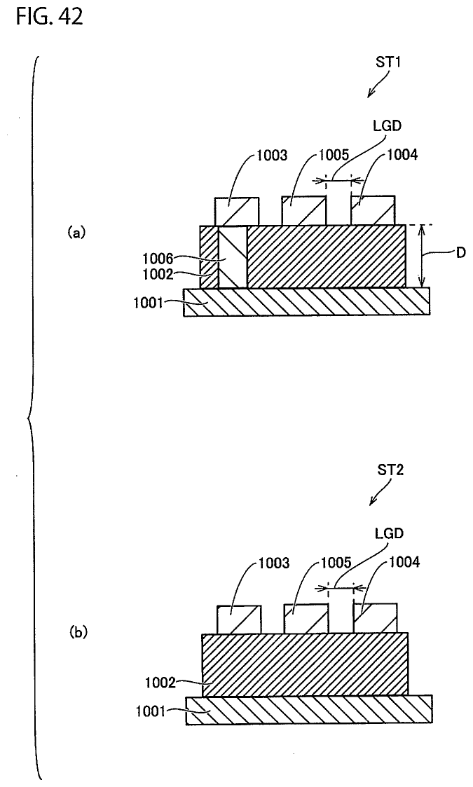

FIG. 42 is a diagram showing structures ST1 and ST2 in the first example of the present invention.

Referring to FIG. 42(a), structure ST1 is a model of the semiconductor device ND1. Structure ST1 includes a conductive substrate 1001 corresponding to the SiC layer 2, a nitride semiconductor layer 1002, source electrode 1003, drain electrode 1004, gate electrode 1005, and a conductive layer 1006. On the conductive substrate 1001, a nitride semiconductor layer 1002 with thickness D is formed. On the nitride semiconductor layer 1002, source electrode 1003, drain electrode 1004, and gate electrode 1005 are formed at intervals from each other. The conductive layer 1006 is formed inside the nitride semiconductor layer 1002, electrically connecting the source electrode 1003 with the conductive substrate 1001.

Referring to FIG. 42(b), structure ST2 has the same structure as structure ST1, except that it does not include the conductive layer 1006. In structure ST2, the source electrode 1003 and the conductive substrate 1001 are not electrically connected.

Sample 1 (Example of the Invention): Sample 1 has structure ST1 and has a thickness D of 2 μm.

Sample 2 (Example of the Invention): Sample 2 has structure ST1 and has a thickness D of 4 μm.

Sample 3 (Example of the Invention): Sample 3 has structure ST1 and has a thickness D of 6 μm.

Sample 4 (Example of the Invention): Sample 4 has structure ST1 and has a thickness D of 8 μm.

Sample 5 (Comparative Example): Sample 5 has structure ST2.

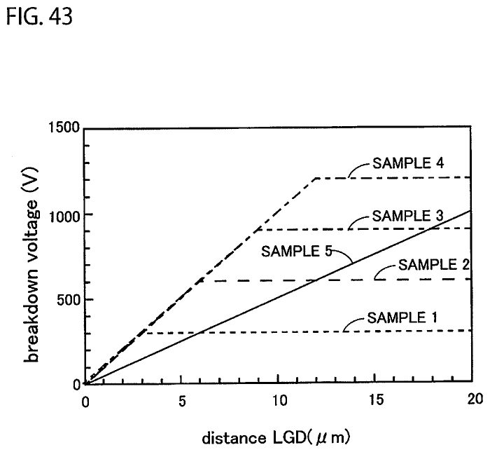

FIG. 43 is a diagram showing the relationship between the gate-drain distance LDG and the breakdown voltage for each of samples 1 to 5 in the first example of the present invention.

Referring to FIG. 43, samples 1 to 4, which electrically connect the source electrode with the conductive substrate, showed a larger increase rate of breakdown voltage with the increase of gate-drain distance LDG compared to sample 5, which does not electrically connect the source electrode with the conductive substrate. The reason why the breakdown voltage of samples 1 to 4 reaches the upper limit at the specified distance LGD is that the insulating state of the nitride semiconductor layer 1002 between the drain electrode 1004 and the conductive substrate 1001 breaks down before the insulating state of the nitride semiconductor layer 1002 between the gate electrode 1005 and the drain electrode 1004 breaks down.

From the above results, it is understood that the breakdown voltage improves in the semiconductor device ND1.

According to a document (“Semiconductor Device Series 4 Power Devices”, edited by Ohashi & Kuzuhara, Maruzen 2011), the breakdown voltage of structure ST1 depends on the smaller of the gate-drain distance LDG and the thickness D of the nitride semiconductor layer, as shown in the following equation (1).

$$Breakdown voltage ( V ) = Min ( 100 ( V / μm ) \times LDG ( μm ) , 150 ( V / μm ) \times D ( μm ) ) \qquad ( 1 )$$

Also, according to a document (J. Vac. Sci. Technol. B 32 (5), 051204 (2014)), the breakdown voltage of structure ST2 depends on the gate-drain distance LDG, as shown in the following equation (2).

$$Breakdown voltage ( V ) = 50 ( V / μm ) \times distance LDG ( μm ) \qquad ( 2 )$$

As a second example, the inventors manufactured samples 6 to 8, each having a structure ST3 or ST4, and calculated the thermal resistance for each of samples 6 to 8.

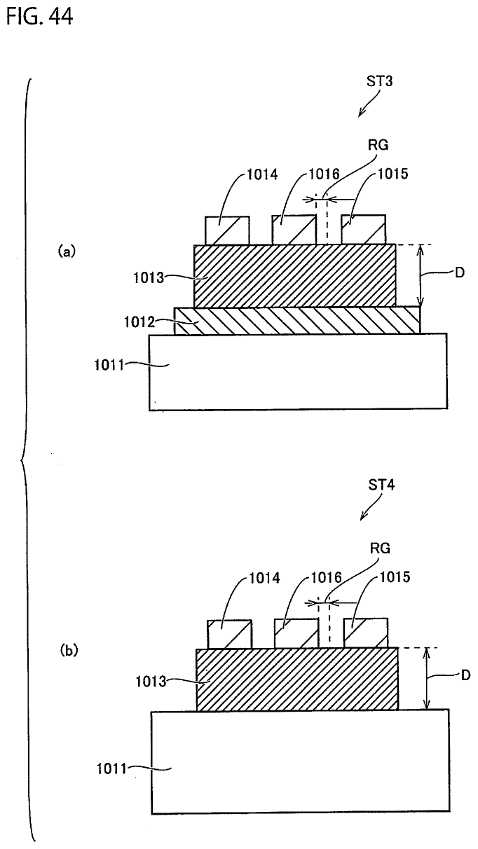

FIG. 44 is a diagram showing structures ST3 and ST4 in the second example of the present invention.

Referring to FIG. 44(a), structure ST3 is a model of the semiconductor device ND1. Structure ST3 includes a substrate 1011, an SiC layer 1012, a nitride semiconductor layer 1013, source electrode 1014, drain electrode 1015, and gate electrode 1016. On the substrate 1011, the SiC layer 1012 and the nitride semiconductor layer 1013 are stacked in this order. On the nitride semiconductor layer 1013, source electrode 1014, drain electrode 1015, and gate electrode 1016 are formed at intervals from each other. The nitride semiconductor layer 1013 has a thickness D of 6 μm.

Referring to FIG. 44(b), structure ST4 is a model of the Non-patent document 1 and has the same structure as structure ST3, except that it does not include the SiC layer 1012.

Sample 6 (Example of the Invention): Sample 6 has structure ST3. The substrate 1011 is made of diamond with a thickness of 300 μm. The SiC layer 2 has a thickness of 1 μm and a 3C crystal structure.

Sample 7 (Comparative Example): Sample 7 has structure ST3. The substrate 1011 is made of Si with a thickness of 300 μm. The SiC layer 2 has a thickness of 1 μm and a 3C crystal structure.

Sample 8 (Comparative Example): Sample 8 has structure ST4. The substrate 1011 is an SOI substrate, including a Si substrate, an SiO₂ layer, and a Si layer. The Si substrate, SiO₂ layer, and Si layer are stacked in this order. The Si substrate has a thickness of 300 μm. The top surface of the Si substrate has a (100) surface orientation. The SiO₂ layer has a thickness of 1 μm. The Si layer has a thickness of 3.5 μm. The top surface of the Si substrate has a (111) surface orientation.

In calculating thermal resistance, it was assumed that heat is generated in the RG region and transferred in a direction within 45 degrees from directly downward. The thermal resistance at the interface between layers was ignored. The RG region has a rectangular shape when viewed from above of structures ST3 and ST4. The RG region is an area within 2 μm from the end of the gate electrode 1016 towards the drain electrode 1015, and within a gate width of 100 μm (length of gate electrode 1016 in the direction perpendicular to the plane).

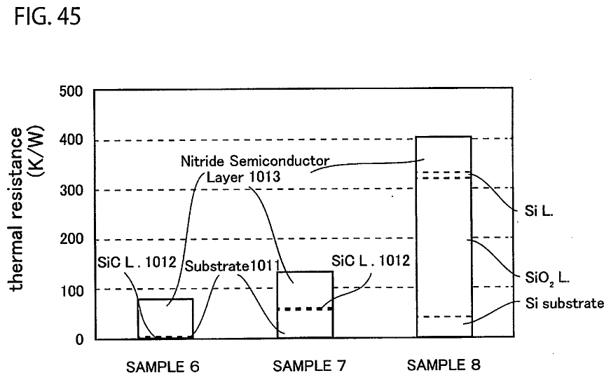

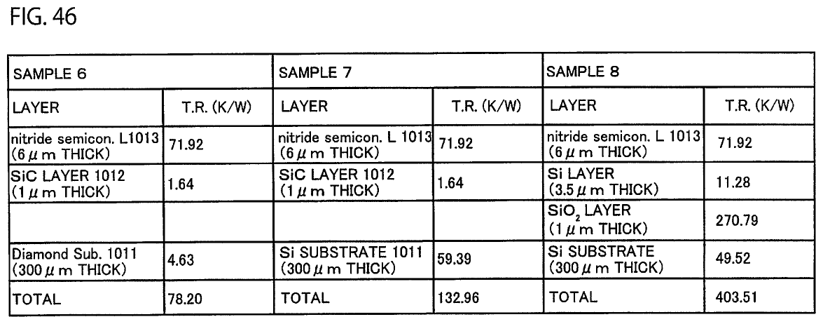

FIG. 45 is a graph showing the total thermal resistance of samples 6 to 8 in the second example of the present invention. FIG. 46 is a table showing the thermal resistance of each of the multiple layers constituting samples 6 to 8 and the total thermal resistance in the second example of the present invention.

Referring to FIGS. 45 and 46, the thermal resistance of sample 6 was 78.20 (K/W), that of sample 7 was 132.96 (K/W), and that of sample 8 was 403.51 (K/W). The thermal resistance of sample 6 was very small compared to that of samples 7 and 8. In sample 7, the thermal resistance of Si composing the substrate 1011 was greater than that of diamond, resulting in an increased thermal resistance compared to sample 6. In sample 8, the thermal resistance of the SiO₂ layer within the substrate 1011 was very high, significantly increasing the thermal resistance compared to samples 6 and 7.

Next, the inventors calculated the relationship between the thermal resistance of samples 6 and 8 and the thickness D of the nitride semiconductor layer 1013.

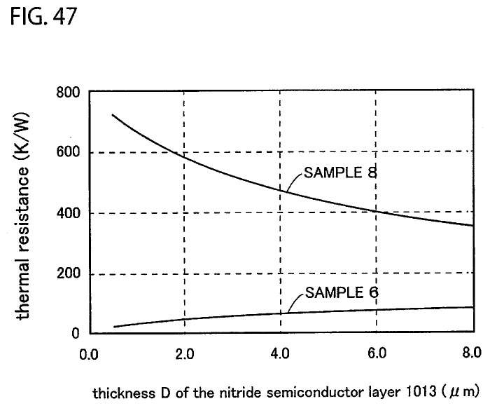

FIG. 47 is a diagram showing the relationship between the thermal resistance of samples 6 and 8 and the thickness D of the nitride semiconductor layer 1013.

Referring to FIG. 47, the thermal resistance of sample 6 increased gradually with the increase of the thickness D of the nitride semiconductor layer 1013. On the other hand, the thermal resistance of sample 8 decreased sharply with the increase of the thickness D of the nitride semiconductor layer 1013.

From the above results, it is understood that the thermal resistance improves in the semiconductor device ND1.

As a third example, the inventors manufactured samples 9 to 11 by the following method to investigate the relationship between heat treatment and the structure of the bonding layer 3.

Sample 9 (Example of the Invention): Using surface activation bonding, the principal surface of the diamond substrate and the principal surface of the 3C SiC layer were bonded. No heat treatment was performed after bonding on the obtained structure.

Sample 10 (Example of the Invention): Using surface activation bonding, the principal surface of the diamond substrate and the principal surface of the 3C SiC layer were bonded. Heat treatment was performed at a temperature of 600° C. after bonding on the obtained structure.

Sample 11 (Example of the Invention): Using surface activation bonding, the principal surface of the diamond substrate and the principal surface of the 3C SiC layer were bonded. Heat treatment was performed at a temperature of 1000° C. after bonding on the obtained structure.

Next, the inventors observed the cross-section of the bonding layer formed at the boundary between the principal surface of the diamond substrate and the principal surface of the SiC layer for each of samples 9 to 11 using TEM (Transmission Electron Microscope). The bonding layer was observed from both the crystal axis direction of diamond and the [−101] crystal axis direction of SiC. FFT (Fast Fourier Transform) patterns were obtained by processing a part of the TEM images. JEM-2200FS made by JEOL Ltd. was used as the TEM. The acceleration voltage was set to 200 kV.

Next, the inventors measured the distribution of atomic density along the depth direction from the surface of the SiC layer for each of samples 9 to 11 using EDS (Energy Dispersive X-ray Spectroscopy). During the measurement of atomic density, the distribution of atomic densities of Si, C, O, Fe, and Ar was measured. JEM-ARM200F made by JEOL Ltd. was used as the EDS device. The acceleration voltage was set to 200 kV, the magnification was set to 1000000.0 times, the emission current was set to 100 μA, the probe current was set to 10.0 nA, and the mapping range was set to a square region of 39.07 nm×39.07 nm. The pixel size was set to 0.15 nm×0.15 nm.

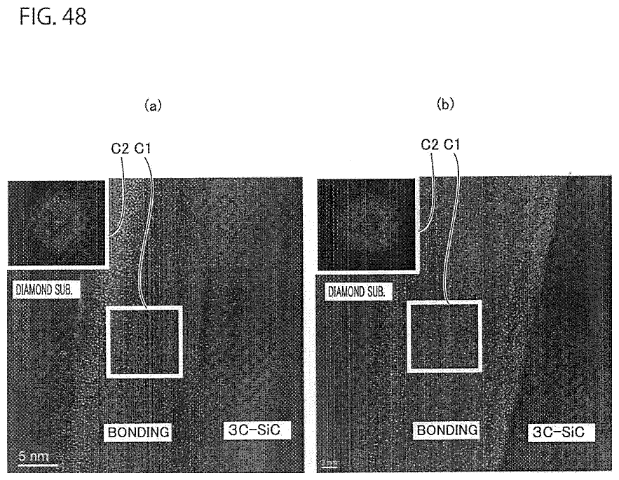

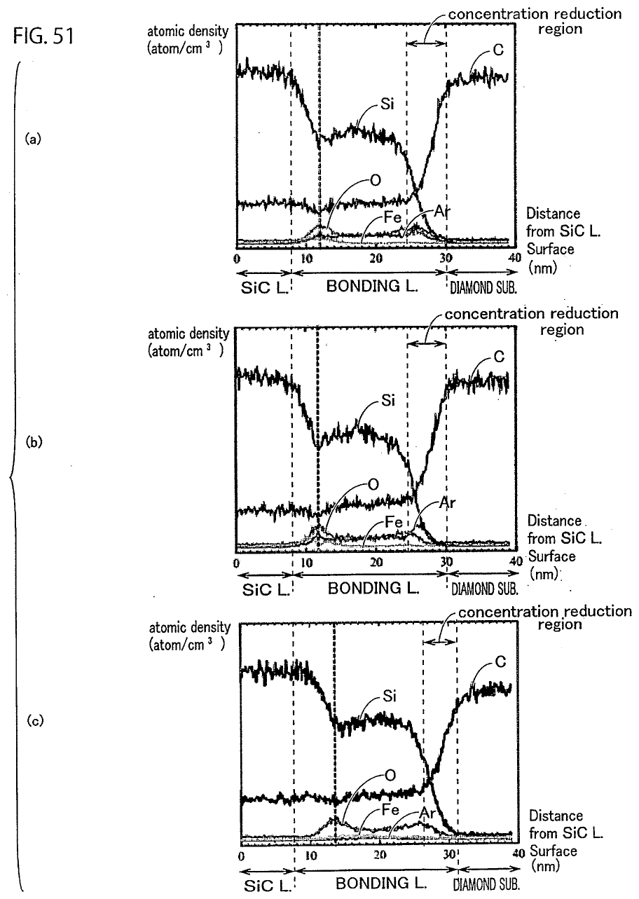

FIGS. 48 to 50 are TEM images of the cross-section of the bonding layer for each of samples 9 to 11 in the third example of the present invention. FIG. 51 is a diagram showing the distribution of atomic density along the depth direction from the surface of the SiC layer for each of samples 9 to 11.

FIGS. 48(a), 49(a), and 50(a) are diagrams of the bonding layer viewed from the crystal axis direction of diamond. FIGS. 48(b), 49(b), and 50(b) are diagrams of the bonding layer viewed from the [−101] crystal axis direction of SiC. In each of FIGS. 48(a), 48(b), 49(a), 49(b), 50(a), and 50(b), the photo C2 in the upper left is the FFT pattern obtained from the region C1 of each of FIGS. 48(a), 48(b), 49(a), 49(b), 50(a), and 50(b). FIG. 51(a) shows the distribution of atomic density for sample 9. FIG. 51(b) shows the distribution of atomic density for sample 10. FIG. 51(c) shows the distribution of atomic density for sample 11.

Referring to FIGS. 48 and 51(a), the FFT pattern of sample 9 did not show clear bright spots indicating the presence of crystals. The interior of the bonding layer of sample 9 was mainly composed of Si and C. From these results, it is understood that when no heat treatment is performed after bonding, the interior of the bonding layer does not contain crystalline grains, and an amorphous layer mainly composed of Si and C exists.

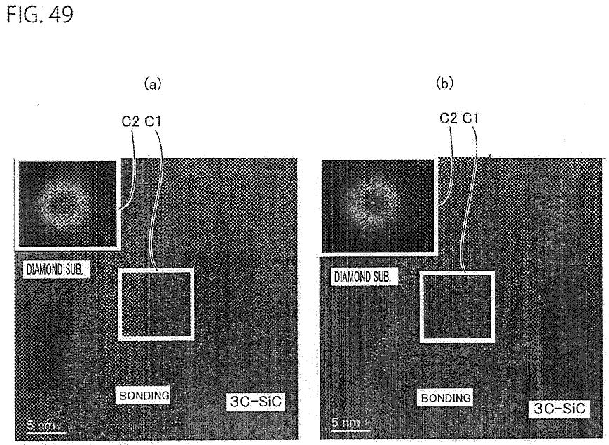

Referring to FIGS. 49 and 51(b), the FFT pattern of sample 10 did not show clear bright spots indicating the presence of crystals. The interior of the bonding layer of sample 10 was mainly composed of Si and C. From these results, it is understood that when heat treatment is performed at a temperature of 600° C. after bonding, similar to the case without heat treatment, the interior of the bonding layer does not contain crystalline grains, and an amorphous layer mainly composed of Si and C exists.

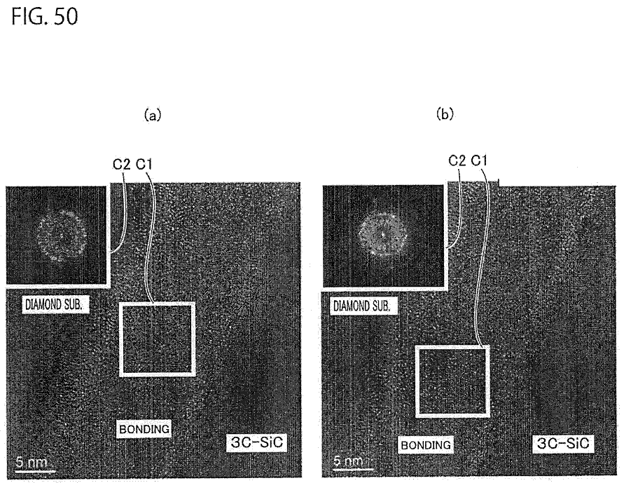

Referring to FIGS. 50 and 51(c), the FFT pattern of sample 11 showed clear bright spots indicating the presence of crystals. These clear bright spots were arranged in various directions on the order of nanometers. Bright spots indicating the presence of an amorphous layer (unclear bright spots) did not appear. The interior of the bonding layer of sample 11 was mainly composed of Si and C. From these results, it is understood that when heat treatment is performed at a temperature of 1000° C. after bonding, the interior of the bonding layer does not contain an amorphous layer, and polycrystalline grains mainly composed of Si and C exist.

It is presumed that at least part of the amorphous layer present before heat treatment recrystallizes due to heat treatment at temperatures exceeding 600° C.

Referring to FIG. 51, in all cases of samples 9 to 11, a concentration reduction region was formed inside the bonding layer. The concentration reduction region is an area where the carbon concentration monotonously decreases from the thermal conduction layer (here, the diamond substrate) towards the SiC layer. The concentration reduction region had a thickness of equal to or more than 4.5 nm.

### [Other]

This disclosure provides a semiconductor substrate, semiconductor device, manufacturing method for a semiconductor substrate, and manufacturing method for a semiconductor device that can improve heat dissipation. This disclosure enables energy-saving effects through the improvement of power energy conversion efficiency of semiconductor devices, contributing to the achievement of sustainable development goals.

The configurations and manufacturing methods of the above-described embodiments, modification examples, and examples can be appropriately combined.

The embodiments, modification examples, and examples described above should be considered illustrative in all aspects and not restrictive. The scope of the invention is indicated by the claims rather than the foregoing description, and all changes that fall within the meaning and range of equivalency of the claims are intended to be embraced therein.

### DESCRIPTION OF REFERENCE NUMERALS

1 Diamond substrate (example of a thermal conduction layer)
1a, 1b Principal surfaces of the diamond substrate
2, 21-23, 1012 SiC (silicon carbide) layer (example of a silicon carbide layer)
2a, 2b, 21a, 22a, 23a Principal surfaces of the SiC layer
3,31-33 Bonding layer (example of a bonding layer)
3a, 3b Amorphous layer (example of first and second amorphous layers)
3c, 3d SiO₂ (silicon oxide) layer
3e Polycrystalline layer
3f Concentration reduction region
4, 41-43, 1002, 1013 Nitride semiconductor layer (example of a nitride semiconductor layer)
4a, 41b, 42b, 43b Principal surfaces of the nitride semiconductor layer
6, 12, 61-63, 121-123 Interlayer insulating layer
6a, 12a, 121b, 122b, 123b Principal surfaces of the interlayer insulating layer
10 Cathode electrode (example of a second electrode)
11 Anode electrode (example of a first electrode)
41a, 42a, 43a, 121a, 122a, 123a Via holes
51, 52, 131-134, 151, 152, 1006 Conductive layer (example of a conductive layer)
71-74, 1003, 1014 Source electrode (example of a first electrode and source electrode)
81-84, 1004, 1015 Drain electrode (example of a second electrode and drain electrode)
90 Si (silicon) substrate
90a Principal surface of the Si substrate
91-94, 1005, 1016 Gate electrode (example of a gate electrode)
95, 96 Support substrate
141, 142 Insulating layer
141a, 142a Principal surfaces of the insulating layer
161, 162 Groove
410 First nitride semiconductor layer (example of a first nitride semiconductor layer)
410a Principal surface of the first nitride semiconductor layer
411 AlN (aluminum nitride) layer
411a Principal surface of the AlN layer
412-415 AlGaN (aluminum gallium nitride) layer
412a, 413a, 414a Principal surfaces of the AlGaN layer
420 Second nitride semiconductor layer (example of a second nitride semiconductor layer)
420a Principal surface of the second nitride semiconductor layer
421, 421a, 421b, 421c C (carbon)-GaN (gallium nitride) layer
422, 422a, 422b Intermediate layer
430 Electron traveling layer (example of an electron transit layer)
430a Principal surface of the electron traveling layer
440 Barrier layer (example of a barrier layer)
1001 Conductive substrate
1011 Substrate
ND1-ND3 Semiconductor device (example of a semiconductor device)
NS1, NS2 Semiconductor substrate (example of a semiconductor substrate)
ST1-ST4 Structure
TE Two-dimensional electron gas
TR1-TR4 Transistor
e1, e2 Electron

1. A semiconductor substrate comprising:
a thermal conduction layer made of diamond or polycrystalline silicon carbide,
a silicon carbide layer formed on one principal surface side of the thermal conduction layer, having a 3C crystal structure,
a bonding layer formed between the thermal conduction layer and the silicon carbide layer, and
a nitride semiconductor layer formed on one principal surface of the silicon carbide layer.

2. The semiconductor substrate according to claim 1, wherein the silicon carbide layer and the nitride semiconductor layer are in contact with each other, and there is no amorphous layer between the silicon carbide layer and the nitride semiconductor layer.

3. The semiconductor substrate according to claim 1, wherein the thermal conduction layer is made of diamond, and the bonding layer includes:
a first amorphous layer mainly composed of carbon and formed on one principal surface of the thermal conduction layer, and
a second amorphous layer mainly composed of carbon and silicon and formed between the first amorphous layer and the silicon carbide layer.

4. The semiconductor substrate according to claim 1, wherein the silicon carbide layer is monocrystalline, the thermal conduction layer is made of diamond, and the bonding layer includes polycrystalline grains of silicon carbide at least.

5. The semiconductor substrate according to claim 1, wherein the thermal conduction layer is made of diamond, and
the bonding layer includes a concentration reduction region of carbon atom density, in which
the carbon atom density in the concentration reduction region monotonically decreases from the thermal conduction layer towards the silicon carbide layer, and
the thickness of the concentration reduction region of carbon atom density is 2 nm or more.

6. The semiconductor substrate according to claim 1, wherein the bonding layer includes silicon oxide.

7. The semiconductor substrate according to claim 1, wherein the silicon carbide layer has a thickness of 0.1 μm to 5 μm.

8. The semiconductor substrate according to claim 1, wherein the one principal surface of the silicon carbide layer has a surface orientation of (1,1,1), (−1,−1,−1), or (1,0,0).

9. The semiconductor substrate according to claim 1, wherein the thermal conduction layer is made of diamond and has a resistivity of 5×10\hat{ }3 Ω·cm to 1×10\hat{ }16 Ω·cm.

10. The semiconductor substrate according to claim 9, wherein the silicon carbide layer has an electron concentration of 1×10\hat{ }15/cm\hat{ }3 to 1×10\hat{ }21/cm\hat{ }3.

11. The semiconductor substrate according to claim 1, wherein the nitride semiconductor layer comprises:
a first nitride semiconductor layer formed on one principal surface side of the silicon carbide layer, including an insulating or semi-insulating layer, made of AlₓGa₁₋ₓN (0.1≤x≤1),
a second nitride semiconductor layer formed on one principal surface side of the first nitride semiconductor layer, including a main layer made of insulating or semi-insulating Al_{y}Ga_{1-y}N (0≤y<0.1), and
an electron transit layer formed on one principal surface side of the second nitride semiconductor layer, made of Al_{z}Ga_{1-z}N (0≤z<0.1), and
a barrier layer formed on one principal surface side of the electron transit layer, having a bandgap wider than that of the electron transit layer,
with the thickness of the nitride semiconductor layer being 6 μm to 10 μm.

12. The semiconductor substrate according to claim 1, wherein the thermal conduction layer is made of diamond,
the nitride semiconductor layer has a thickness of 0.5 μm to less than 6 μm,
the thermal conduction layer has a resistivity of 5×10\hat{ }3 Ω·cm to 1×10\hat{ }16 Ω·cm, and
the silicon carbide layer has a resistivity of 1×10\hat{ }3 Ω·cm to 1×10\hat{ }16 Ω·cm.

13. A semiconductor device comprising:
the semiconductor substrate according to claim 1, and
first and second electrodes formed on one principal surface side of the silicon carbide layer, wherein
the first electrode is electrically connected to the silicon carbide layer.

14. The semiconductor device according to claim 13, wherein
the nitride semiconductor layer includes a via hole reaching the silicon carbide layer from one principal surface of the nitride semiconductor layer,
the first electrode is formed on the one principal surface of the nitride semiconductor layer, and the semiconductor device further comprising:
a conductive layer that electrically connects the first electrode to the silicon carbide layer, formed inside the via hole.

15. The semiconductor device according to claim 13, wherein
each of the silicon carbide layer, the nitride semiconductor layer, and the first and second electrodes are plural,
each of the plural silicon carbide layers is formed on the one principal surface side of the thermal conduction layer and insulated from each other,
each of the plural nitride semiconductor layers is formed on the one principal surface of each of the plural silicon carbide layers, and
each of the plural first and second electrodes is formed on the one principal surface side of each of the plural silicon carbide layers.

16. A semiconductor device comprising:
the semiconductor substrate according to claim 1, and
a source electrode and a gate electrode formed on one principal surface of the nitride semiconductor layer, and
a drain electrode formed on one principal surface of the silicon carbide layer.

17. A method for manufacturing a semiconductor substrate, comprising:
forming a silicon carbide layer with a 3C crystal structure on one principal surface of a silicon substrate,
forming a nitride semiconductor layer on one principal surface of the silicon carbide layer,
removing the silicon substrate from the silicon carbide layer, and
bonding other principal surface of the silicon carbide layer with one principal surface of a thermal conduction layer made of diamond or polycrystalline silicon carbide.

18. The method for manufacturing a semiconductor substrate according to claim 17, wherein the step of forming the silicon carbide layer includes:
forming a first silicon carbide layer by carbonizing one principal surface of the silicon substrate, and
forming a second silicon carbide layer by crystalline growth of silicon carbide on one principal surface of the first silicon carbide layer.

19. A method for manufacturing a semiconductor device, comprising:
manufacturing a semiconductor substrate by the method according to claim 17,
forming first and second electrodes on the one principal surface side of the silicon carbide layer, and
electrically connecting the first electrode to the silicon carbide layer.

20. A method for manufacturing a semiconductor device, comprising:
forming a silicon carbide layer with a 3C crystal structure on one principal surface of a silicon substrate,
manufacturing a semiconductor substrate by forming a nitride semiconductor layer on one principal surface of the silicon carbide layer,
manufacturing a device on the semiconductor substrate,
exposing the other principal surface of the silicon carbide layer by removing the silicon substrate after manufacturing the device, and
bonding the other principal surface of the silicon carbide layer with one principal surface of a thermal conduction layer made of diamond or polycrystalline silicon carbide after exposing the other principal surface of the silicon carbide layer.
